(19) United States
(12) Patent Application Publication
(10) Pub. No.: US 2024/0337919 A1
(43) Pub. Date: Oct. 10, 2024

(54) MASK BLANK, PHASE SHIFT MASK, AND METHOD FOR PRODUCING SEMICONDUCTOR DEVICE

(71) Applicant: HOYA CORPORATION, Tokyo (JP)

(72) Inventors: Kenta TSUKAGOSHI, Tokyo (JP); Osamu NOZAWA, Tokyo (JP); Ryo OHKUBO, Tokyo (JP); Hitoshi MAEDA, Tokyo (JP)

(73) Assignee: HOYA CORPORATION, Tokyo (JP)

(21) Appl. No.: 18/681,934

(22) PCT Filed: Jun. 30, 2022
(86) PCT No.: PCT/JP2022/026236

§ 371 Date: Feb. 7, 2024

(30) Foreign Application Priority Data
Sep. 8, 2021 (JP) 2021-146180

(51) Int. Cl. G03F 1/30; G03F 1/34

(52) U.S. Cl. CPC G03F 1/30; G03F 1/34

(57) ABSTRACT

Provided are a mask blank, a phase shift mask, and a method of manufacturing a semiconductor device. A mask blank comprises a light-shielding film on a transparent substrate. The light-shielding film is made of a material comprising silicon and nitrogen. An internal region of the light-shielding film has a maximum peak at a binding energy in a range in which a Si2p narrow spectrum obtained by analysis by X-ray photoelectron spectroscopy is more than 100 eV and 101.5 eV or less. The internal region of the light-shielding film is a region obtained by excluding a back surface side region on the transparent substrate side and a front surface side region opposite to the transparent substrate.

### CROSS-REFERENCE TO RELATED APPLICATIONS

This application is the National Stage of International Application No. PCT/JP2022/026236, filed Jun. 30, 2022, which claims priority to Japanese Application No. 2021-146180, filed Sep. 8, 2021, and the contents of which is incorporated by reference.

### TECHNICAL FIELD

The present disclosure relates to a mask blank, a phase shift mask, and a method of manufacturing a semiconductor device.

### BACKGROUND ART

In a semiconductor device manufacturing process, a fine pattern is formed using a photolithography method. Many transfer masks are usually used for forming the fine pattern. In order to miniaturize the pattern of the semiconductor device, it is necessary to miniaturize a mask pattern formed on the transfer mask and to shorten a wavelength of an exposure light source used in photolithography. In recent years, an ArF excimer laser (wavelength: 193 nm) has been increasingly applied to an exposure light source when a semiconductor device is manufactured.

There are various types of transfer masks, and among these, a binary mask and a halftone phase shift mask are widely used. A conventional binary mask and a conventional halftone phase shift mask generally each include a light-shielding pattern made of a chromium-based material, but in recent years, those in which a light-shielding film is made of a material containing silicon and nitrogen have started to be used.

Patent Document 1 discloses a mask blank including a light-shielding film for forming a transfer pattern on a transparent substrate, in which the light-shielding film is made of a material composed of silicon and nitrogen or a material further containing one or more elements selected from a metalloid element and a nonmetallic element, a ratio obtained by dividing the number of existing Si₃N₄ bonds in an internal region obtained by excluding a region near an interface of the light-shielding film with the transparent substrate and a surface layer region of the light-shielding film opposite to the transparent substrate by the total number of existing Si₃N₄ bonds, SiₐN_{b} bonds (in which b/[a+b]<4/7), and Si—Si bonds is 0.04 or less, and a ratio obtained by dividing the number of existing SiₐN_{b} bonds in the internal region of the light-shielding film by the total number of existing Si₃N₄ bonds, SiₐN_{b} bonds, and Si—Si bonds is 0.1 or more.

Meanwhile, Patent Document 2 discloses a photomask including a transparent substrate and a light-shielding film formed on the transparent substrate, containing silicon and nitrogen, and not containing a transition metal, in which the light-shielding film is constituted by a single layer or a multilayer, contains silicon and nitrogen as a layer constituting the single layer or the multilayer, does not contain a transition metal, and has a ratio of nitrogen to the total of silicon and nitrogen of 3 atom % or more and 50 atom % or less.

### PRIOR ART DOCUMENTS

### Patent Documents

Patent Document 1: JP 2018-205400 A
Patent Document 2: JP 2017-161889 A

### Summary of Disclosure

### Technical Problem

The light-shielding film made of a material containing silicon and nitrogen and not containing a transition metal (hereinafter, referred to as a SiN-based material) as disclosed in Patent Documents 1 and 2 can be patterned by dry etching using a gas containing fluorine. In general, dry etching using a fluorine-containing gas has a larger tendency of anisotropic etching than a case of using a chlorine-based gas and an oxygen-based gas, and suppresses a side etching amount.

However, in recent years, there has been an increasing demand for miniaturization and high accuracy of a pattern of a transfer mask, and a conventional light-shielding film cannot sufficiently suppress the side etching amount. In addition, when the film thickness of the light-shielding film is reduced in order to suppress the side etching amount, there is a problem that required light-shielding performance is not satisfied.

Therefore, the present disclosure has been made in order to solve the conventional problem, and an aspect of the present disclosure is to provide a mask blank, a phase shift mask, and a method of manufacturing a semiconductor device, in which the mask blank and the phase shift mask each include a light-shielding film that has desired light-shielding performance, can suppress an increase in film thickness, can reduce a side etching amount generated by dry etching when a pattern is formed, and can form a fine pattern with high accuracy.

### Solution to Problem

In order to achieve the above aspects, the present disclosure has the following configurations.

### (Configuration 1)

A mask blank comprising a light-shielding film on a transparent substrate, in which
the light-shielding film is made of a material comprising silicon and nitrogen,
an internal region of the light-shielding film has a maximum peak at a binding energy in a range in which a Si₂p narrow spectrum obtained by analysis by X-ray photoelectron spectroscopy is more than 100 eV and 101.5 eV or less, and
the internal region of the light-shielding film is a region obtained by excluding a back surface side region on the transparent substrate side and a front surface side region opposite to the transparent substrate.

### (Configuration 2)

The mask blank according to configuration 1, in which a total content of silicon and nitrogen in the internal region is 95 atom % or more.

### (Configuration 3)

The mask blank according to configuration 1 or 2, in which a nitrogen content in the internal region is 30 atom % or more and less than 50 atom %.

### (Configuration 4)

The mask blank according to any one of configurations 1 to 3, in which the front surface side region is a region extending from a surface of the light-shielding film opposite to the transparent substrate to a depth of 5 nm toward the transparent substrate side.

### (Configuration 5)

The mask blank according to any one of configurations 1 to 4, in which the back surface side region is a region extending from a surface of the light-shielding film on the transparent substrate side to a depth of 5 nm toward the front surface side region side.

### (Configuration 6)

The mask blank according to any one of configurations 1 to 5, in which an X-ray with which the light-shielding film is irradiated in the X-ray photoelectron spectroscopy is an Alkα ray.

### (Configuration 7)

The mask blank according to any one of configurations 1 to 6, in which a ratio of a total existence ratio of a Si₃N₄ bond and a Si No bond (in which b/[a+b]<4/7) to a total existence ratio of the Si₃N₄ bond, the SiₐN_{b} bond, and a Si—Si bond in the internal region is 0.5 or more.

### (Configuration 8)

The mask blank according to configuration 7, in which a ratio of an existence ratio of the SiₐN_{b} bond to the total existence ratio of the Si₃N₄ bond, the SiₐN_{b} bond, and the Si—Si bond in the internal region is 0.5 or more.

### (Configuration 9)

The mask blank according to configuration 7 or 8, in which a ratio of an existence ratio of the Si₃N₄ bond to the total existence ratio of the Si₃N₄ bond, the SiₐN_{b} bond, and the Si—Si bond in the internal region is 0.03 or more.

### (Configuration 10)

The mask blank according to any one of configurations 1 to 9, in which a phase shift film is disposed between the transparent substrate and the light-shielding film, the phase shift film being made of a material which is etchable by dry etching using a gas including fluorine.

### (Configuration 11)

A phase shift mask comprising: a phase shift film having a transfer pattern; and a light-shielding film having a pattern comprising a light-shielding band on a transparent substrate, in which
the phase shift film is made of a material which is etchable by dry etching using a gas including fluorine,
the light-shielding film is made of a material comprising silicon and nitrogen,
an internal region of the light-shielding film has a maximum peak at a binding energy in a range in which a Si₂p narrow spectrum obtained by analysis by X-ray photoelectron spectroscopy is more than 100 eV and 101.5 eV or less, and
the internal region of the light-shielding film is a region obtained by excluding a back surface side region on the transparent substrate side and a front surface side region opposite to the transparent substrate.

### (Configuration 12)

The phase shift mask according to configuration 11, in which a total content of silicon and nitrogen in the internal region is 95 atom % or more.

### (Configuration 13)

The phase shift mask according to configuration 11 or 12, in which a nitrogen content in the internal region is 30 atom % or more and less than 50 atom %.

### (Configuration 14)

The phase shift mask according to any one of configurations 11 to 13, in which the front surface side region is a region extending from a surface of the light-shielding film opposite to the transparent substrate to a depth of 5 nm toward the transparent substrate side.

### (Configuration 15)

The phase shift mask according to any one of configurations 11 to 14, in which the back surface side region is a region extending from a surface of the light-shielding film on the transparent substrate side to a depth of 5 nm toward the front surface side region side.

### (Configuration 16)

The phase shift mask according to any one of configurations 11 to 15, in which an X-ray with which the light-shielding film is irradiated in the X-ray photoelectron spectroscopy is an Alkα ray.

### (Configuration 17)

The phase shift mask according to any one of configurations 11 to 16, in which a ratio of a total existence ratio of a Si₃N₄ bond and a SiₐN_{b} bond (in which b/[a+b]<4/7) to a total existence ratio of the Si₃N₄ bond, the SiₐN_{b} bond, and a Si—Si bond in the internal region is 0.5 or more.

### (Configuration 18)

The phase shift mask according to configuration 17, in which a ratio of an existence ratio of the SiₐN_{b} bond to the total existence ratio of the Si₃N₄ bond, the SiₐN_{b} bond, and the Si—Si bond in the internal region is 0.5 or more.

### (Configuration 19)

The phase shift mask according to configuration 17 or 18, in which a ratio of an existence ratio of the Si₃N₄ bond to the total existence ratio of the Si₃N₄ bond, the SiₐN_{b} bond, and the Si—Si bond in the internal region is 0.03 or more.

### (Configuration 20)

A method of manufacturing a semiconductor device, the method comprising performing exposure transfer of the transfer pattern to a resist film on a semiconductor substrate using the phase shift mask according to any one of configurations 11 to 19.

### Advantageous Effects of Disclosure

The present disclosure can provide a mask blank, a phase shift mask, and a method of manufacturing a semiconductor device, in which the mask blank and the phase shift mask each include a light-shielding film that has desired light-shielding performance, can suppress an increase in film thickness, can reduce a side etching amount generated by dry etching when a pattern is formed, and can form a fine pattern with high accuracy.

### BRIEF DESCRIPTION OF DRAWINGS

FIGS. 1A-1D are cross-sectional views illustrating a configuration of a mask blank according to a first embodiment of the present disclosure and a binary mask manufacturing process using the mask blank.

FIGS. 2A-2F are cross-sectional views illustrating a configuration of a mask blank according to a second embodiment of the present disclosure and a phase shift mask manufacturing process using the mask blank.

FIGS. 3A-3G are cross-sectional views illustrating a configuration of a mask blank according to a third embodiment of the present disclosure and a phase shift mask manufacturing process using the mask blank.

FIG. 4 is a diagram illustrating a result of performing X-ray photoelectron spectroscopy on an internal region of a light-shielding film of a mask blank according to Example 1 of the present disclosure.

FIG. 5 is a diagram illustrating a result of performing X-ray photoelectron spectroscopy on an internal region of a light-shielding film of a mask blank according to Example 2 of the present disclosure.

FIG. 6 is a diagram illustrating a result of performing X-ray photoelectron spectroscopy on an internal region of a light-shielding film of a mask blank according to Comparative Example 1 of the present disclosure.

### DESCRIPTION OF EMBODIMENTS

First, circumstances leading to completion of the present disclosure will be described.

The present inventors made intensive studies on a configuration of a light-shielding film that has desired light-shielding performance, can suppress an increase in film thickness, can reduce a side etching amount generated by dry etching when a pattern is formed, and can form a fine pattern with high accuracy. First, the present inventors considered to increase a nitrogen content in a light-shielding film made of a SiN-based material. However, when a large amount of nitrogen is contained in the light-shielding film (for example, 50 atom % or more), a side etching amount can be reduced, but there has newly occurred a problem that an etching rate itself, which is important when a pattern is formed, also decreases. Note that the etching rate in this case refers to an etching rate in a film thickness direction of the light-shielding film when the light-shielding film is dry-etched (The same applies hereinafter).

Therefore, the present inventors expected that by adjusting the nitrogen content in the light-shielding film within a predetermined range, the side etching amount would be reduced while the etching rate at the time of patterning the light-shielding film by dry etching could be set to a predetermined value or more, and further made studies. However, it was newly found that in a case where the nitrogen content in the light-shielding film was used as an index, it was not easy to adjust both the etching rate and the side etching amount so as to be suitable. In a case of a SiN film having a nitrogen content of 50 atom % or less, it is presumed that different bonding states of Si and N are mixed in the film (for example, a Si₃N₄ bond, a SiN bond and/or a Si—Si bond that is not stoichiometrically stable). In a case of a SiN film formed by reactive sputtering, even when SiN films having the same nitrogen content are formed, the films may have different bonding states of Si and N depending on film formation conditions.

Therefore, the present inventors focused on a maximum peak of a Si₂p narrow spectrum obtained by analysis by X-ray photoelectron spectroscopy in an internal region of the light-shielding film, and further made studies. Here, the internal region of the light-shielding film is a region which excludes a back surface side region on a transparent substrate and a front surface side region which is opposite to the transparent substrate. It has been found that when the maximum peak is 100 eV or less, it is difficult to sufficiently suppress the side etching amount in the light-shielding film having a desired film thickness. Meanwhile, it has been found that when the maximum peak is more than 101.5 eV, the etching rate of the light-shielding film largely decreases. Furthermore, it has also been found that an optical density (OD) per unit film thickness decreases, and thus the film thickness for ensuring light-shielding performance against ArF exposure light increases.

Note that a reason why the detection target of the maximum peak is the internal region which excludes the back surface side region and the front surface side region from the light-shielding film is as follows. In the light-shielding film of a SiN-based material, oxidation of the front surface side region which is exposed to the atmosphere (surface side region opposite to the transparent substrate) cannot be avoided. Furthermore, it is estimated that the back surface side region on an interface with the transparent substrate is configured similarly to the internal region which excludes the back surface side region and the front surface side region, but even when analysis is performed by X-ray photoelectron spectroscopy (XPS), an analysis result thereof is inevitably affected by a composition of the transparent substrate.

Note that even when the back surface side region and the front surface side region are excluded, a ratio thereof with respect to the total film thickness of the light-shielding film is small, and thus, it is considered that an influence thereof is small.

As described above, the present inventors have found that when the internal region of the light-shielding film has a maximum peak at a binding energy in a range in which a Si₂p narrow spectrum obtained by analysis by X-ray photoelectron spectroscopy is more than 100 eV and 101.5 eV or less, the light-shielding film has desired light-shielding performance, can suppress an increase in film thickness, can reduce a side etching amount generated by dry etching when a pattern is formed, and can form a fine pattern with high accuracy.

The present disclosure has been completed as a result of intensive studies as described above.

Next, embodiments of the present disclosure will be described.

### First Embodiment

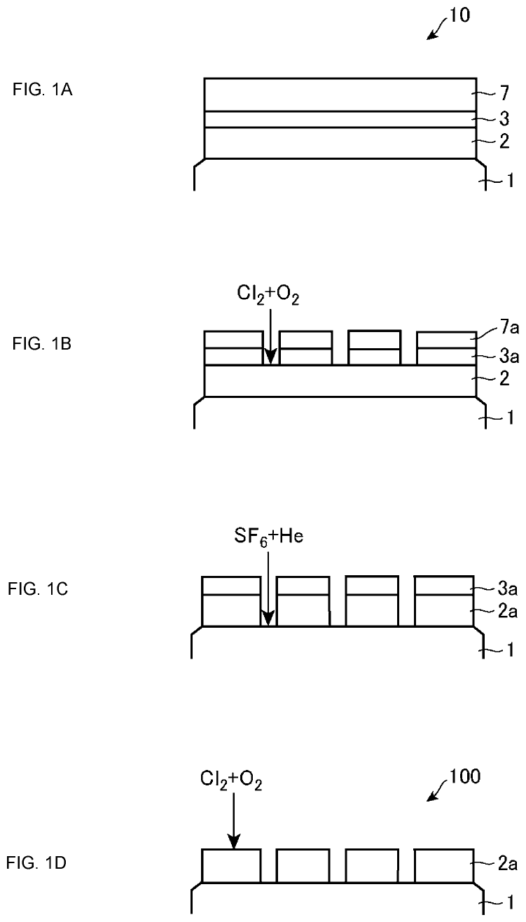

A mask blank according to a first embodiment of the present disclosure includes a light-shielding film having a predetermined optical density as a pattern forming thin film, and is used for manufacturing a binary mask (transfer mask). FIGS. 1A-1D are cross-sectional views illustrating a configuration of the mask blank according to the first embodiment of the present disclosure and a binary mask manufacturing process using the mask blank. FIG. 1A is a cross-sectional view illustrating a configuration of a mask blank 10 according to the first embodiment of the present disclosure.

The mask blank 10 illustrated in FIG. 1A has a structure in which a light-shielding film 2, a hard mask film 3, and a resist film 7 are layered in this order on a transparent substrate 1.

The transparent substrate 1 is made of a material containing silicon and oxygen, and can be made of a glass material such as a synthetic quartz glass, a quartz glass, an aluminosilicate glass, a soda lime glass, or a low thermal expansion glass (a SiO₂—TiO₂ glass or the like). Among these glasses, a synthetic quartz glass has a high transmittance to ArF exposure light, and is particularly preferable as a material for forming a transparent substrate of a mask blank.

The light-shielding film 2 is a single-layer film made of a silicon nitride-based material. The silicon nitride-based material in the present disclosure is a material composed of silicon and nitrogen, or a material composed of one or more elements selected from a metalloid element and a nonmetallic element, silicon, and nitrogen. In addition, by forming the light-shielding film 2 into a single-layer film, the number of manufacturing steps is reduced, manufacturing efficiency is increased, and quality control at the time of manufacturing including defects is facilitated. In addition, the light-shielding film 2 is made of a silicon nitride-based material, and therefore has high ArF light resistance.

The light-shielding film 2 may contain any metalloid element in addition to silicon. Among these metalloid elements, inclusion of one or more elements selected from boron, germanium, antimony, and tellurium is preferable because conductivity of silicon used as a sputtering target can be expected to be enhanced.

In addition, the light-shielding film 2 may contain any nonmetallic element in addition to nitrogen. The nonmetallic element in the present disclosure refers to those including a nonmetallic element in a narrow sense (nitrogen, carbon, oxygen, phosphorus, sulfur, selenium, and hydrogen), a halogen (fluorine, chlorine, bromine, iodine, and the like), and a noble gas. Among these nonmetallic elements, one or more elements selected from carbon, fluorine, and hydrogen are preferably contained. In the light-shielding film 2 except for a front surface side region described later, an oxygen content is preferably suppressed to 10 atom % or less, more preferably 5 atom or less, and still more preferably, oxygen is not actively contained (When composition analysis is performed by X-ray photoelectron spectroscopy or the like, a value for oxygen is a lower detection limit or less).

The noble gas is an element that can increase a film forming speed and improve productivity by existing in a film forming chamber when the light-shielding film 2 is formed by reactive sputtering. The noble gas is turned into plasma and collides with a target, whereby a target constituent element jumps out from the target, and the light-shielding film 2 is formed on the transparent substrate 1 while taking in a reactive gas. The noble gas in the film forming chamber is slightly taken in while the target constituent element jumps out from the target and adheres to the transparent substrate 1. Preferable examples of the noble gas required for this reactive sputtering include argon, krypton, and xenon. In order to alleviate a stress of the light-shielding film 2, helium and neon each having a small atomic weight may be actively taken into the light-shielding film 2.

The light-shielding film 2 is preferably made of a material composed of silicon and nitrogen. As described above, the noble gas is slightly taken in when the light-shielding film 2 is formed by reactive sputtering. However, the noble gas is an element that is not easily detected even when composition analysis such as Rutherford back-scattering spectrometry (RBS) or X-ray photoelectron spectroscopy (XPS) is performed on the light-shielding film 2. Therefore, it can be considered that the material composed of silicon and nitrogen also includes a material containing the noble gas.

The inside of the light-shielding film 2 is divided into three regions in order of a back surface side region, an internal region, and a front surface side region from the transparent substrate 1 side. The back surface side region is a region which extends to a depth of 5 nm (more preferably a depth of 4 nm, still more preferably a depth of 3 nm) from an interface between the light-shielding film 2 and the transparent substrate 1 toward a front surface (that is, the front surface side region) which is opposite to the transparent substrate 1. In a case where X-ray photoelectron spectroscopy is performed on the back surface side region, the back surface side region is easily affected by the transparent substrate 1 present under the back surface side region, and thus accuracy of a maximum peak of a photoelectron intensity in an acquired Si₂p narrow spectrum of the back surface side region is low.

The front surface side region is a region which extends to a depth of 5 nm (more preferably a depth of 4 nm, still more preferably a depth of 3 nm) from a surface opposite to the transparent substrate 1 toward the transparent substrate 1. The front surface side region is a region containing oxygen taken in from a surface of the light-shielding film 2, and therefore has a structure in which an oxygen content has a composition gradient in a thickness direction of the film (a structure having a composition gradient in which the oxygen content in the film increases as a distance from the transparent substrate 1 increases). That is, the front surface side region has a larger oxygen content than the internal region.

The internal region is a region of the light-shielding film 2 which excludes the back surface side region and the front surface side region. The internal region has a maximum peak at a binding energy in a range in which a Si2p narrow spectrum obtained by analysis by X-ray photoelectron spectroscopy is more than 100 eV and 101.5 eV or less. The maximum peak is preferably 101.3 eV or less, more preferably 101.2 eV or less, and still more preferably 101.1 eV or less, from a viewpoint of further suppressing the film thickness while ensuring light-shielding performance. In addition, the maximum peak is preferably 100.1 eV or more, more preferably 100.3 eV or more, and still more preferably 100.5 eV or more, from a viewpoint of further suppressing the side etching amount.

Here, the internal region is made of a material in which a total content of silicon and nitrogen is preferably 95 atom % or more, more preferably 97 atom % or more, and still more preferably 98 atom % or more. Meanwhile, in the internal region, a difference in content of each element constituting the internal region in the film thickness direction is preferably less than 10%. The nitrogen content in the internal region is preferably 30 atom % or more, more preferably 35 atom % or more, and still more preferably 37 atom % or more. Meanwhile, the nitrogen content in the internal region is preferably less than 50 atom %, more preferably 48 atom % or less, and still more preferably 45 atom % or less.

In a case where X-ray photoelectron spectroscopy (XPS) is performed, the back surface side region on the interface with the transparent substrate 1 is inevitably affected by the transparent substrate 1, and therefore it is difficult to specify a Si₂p narrow spectrum and numerical values for the number of existing Si bonds and the number of existing N bonds derived from the Si₂p narrow spectrum. However, it is estimated that the back surface side region is configured similarly to the above-described internal region.

The light-shielding film 2 most preferably has an amorphous structure because pattern edge roughness is favorable when a pattern is formed by etching. In a case where the light-shielding film 2 has a composition which is difficult to make the light-shielding film 2 to have an amorphous structure, the light-shielding film 2 is preferably in a state where an amorphous structure and a microcrystalline structure are mixed.

The thickness of the light-shielding film 2 is 80 nm or less, preferably 70 nm or less, and more preferably 60 nm or less. When the thickness is 80 nm or less, a fine pattern of the light-shielding film is easily formed, and a load at the time of manufacturing a transfer mask from a mask blank having the light-shielding film is also reduced. In addition, the thickness of the light-shielding film 2 is preferably 30 nm or more, more preferably 40 nm or more, and still more preferably 45 nm or more. When the thickness is less than 30 nm, it is difficult to obtain sufficient light-shielding performance with respect to ArF exposure light. Meanwhile, a ratio of the thickness of the internal region to the total thickness of the light-shielding film 2 is preferably 0.7 or more, and more preferably 0.75 or more.

An optical density of the light-shielding film 2 to ArF exposure light is preferably 2.5 or more, and more preferably 3.0 or more. When the optical density is 2.5 or more, sufficient light-shielding performance can be obtained. Therefore, when exposure is performed using a transfer mask manufactured using the mask blank, sufficient contrast of a projection optical image (transfer image) thereof can be easily obtained. In addition, the optical density of the light-shielding film 2 to ArF exposure light is preferably 4.0 or less, and more preferably 3.5 or less. When the optical density exceeds 4.0, the film thickness of the light-shielding film 2 increases, and thus it is difficult to form a fine pattern of the light-shielding film.

Note that in the light-shielding film 2, oxidation of a surface layer opposite to the transparent substrate 1 proceeds. Therefore, the surface layer of the light-shielding film 2 has a different composition and a different optical characteristic from those of the other regions of the light-shielding film 2.

An antireflection film may be layered on the light-shielding film 2. The antireflection film preferably contains a larger amount of oxygen than the light-shielding film 2. The antireflection film is made of, for example, a material containing silicon and oxygen.

In the X-ray photoelectron spectroscopy described above, either an AlKα ray or an MgKα ray can be applied as the X-ray with which the light-shielding film 2 is irradiated, but an AlKα ray is preferably used. Note that, in the present specification, a case where X-ray photoelectron spectroscopy using an X-ray of an Alkα ray is performed is described.

A method of acquiring a Si₂p narrow spectrum by performing X-ray photoelectron spectroscopy on the light-shielding film 2 is generally performed by the following procedure. That is, first, wide scan for acquiring a photoelectron intensity (the number of photoelectrons emitted per unit time from a measurement object irradiated with an X-ray) with a wide band width of binding energy is performed to acquire a wide spectrum, and a peak derived from a constituent element of the light-shielding film 2 is specified. Thereafter, narrow scan having a resolution higher than that of the wide scan but having a narrow band width of binding energy that can be acquired is performed at a band width around a peak (Si₂p in this case) of interest to acquire a narrow spectrum. Meanwhile, the constituent element of the light-shielding film 2 which is an object of measurement using X-ray photoelectron spectroscopy in the present disclosure is known in advance. In addition, the narrow spectrum required in the present disclosure is limited to a Si₂p narrow spectrum and a N1s narrow spectrum. Therefore, in the case of the present disclosure, the step of acquiring the wide spectrum may be omitted, and the Si₂p narrow spectrum may be acquired.

The present inventors made intensive studies also on a bonding state inside a SiN-based material after studying the above-described binding energy regarding the Si2p narrow spectrum. It is considered that, inside the SiN-based material, a Si—Si bond which is in a non-bonded state with an element other than silicon, a Si₃N₄ bond which is in a stoichiometrically stable bonded state, and a SiₐN_{b} bond (in which b/[a+b]<4/7. The same applies hereinafter) which is in a relatively unstable bonded state mainly exist.

In general, in dry etching that proceeds in a film thickness direction with respect to a thin film containing silicon and nitrogen, both etching by a chemical reaction and etching by a physical action are performed. Etching by a chemical reaction is performed in a process in which an etching gas in a plasma state is brought into contact with a surface of a thin film and is bonded to silicon in the thin film to generate a low boiling point compound, and sublimation occurs. In etching by a chemical reaction, a bond of silicon bonded to another element is cleaved to generate a low boiling point compound. On the other hand, physical etching is performed in a process in which ionic plasma in an etching gas accelerated by a bias voltage collides with a surface of a thin film (This phenomenon is also referred to as “ion bombardment”), thereby physically repelling each element containing silicon on the surface of the thin film (At this time, a bond between elements is cleaved), and bonding to the silicon to generate a low boiling point compound which is to sublimate.

Meanwhile, in side etching that proceeds in a direction perpendicular to the film thickness direction of the thin film, etching by a chemical reaction is dominant. In a case of a Si—Si bond, an etching gas is relatively easily bonded to Si to form a low boiling point compound, and the low boiling point compound is volatilized. That is, the Si—Si bond is easily etched by etching by a chemical reaction. On the other hand, in a case of a state in which silicon and nitrogen are bonded, that is, in a case of a Si No bond and a Si₃N₄ bond, in order to cause the etching gas to be bonded to silicon to form a low boiling point compound, it is necessary to cleave a bond between silicon and nitrogen, and etching is less likely to be performed than the case of the Si—Si bond. The present inventors considered that the side etching amount might be reduced by adjusting existence ratios of a SiₐN_{b} bond and a Si₃N₄ bond in the thin film. The present inventors further studied a relationship among the number of existing Si₃N₄ bonds, the number of existing SiₐN_{b} bonds, and the number of existing Si—Si bonds in the SiN-based material forming the light-shielding film for a narrow spectrum in which a maximum peak of binding energy satisfies the above-described desired range. As a result, the present inventors have found that the following relationship is preferably satisfied.

That is, a ratio of a total existence ratio of a Si₃N₄ bond and a SiₐN_{b} bond to a total existence ratio of the Si₃N₄ bond, the Si No bond, and a Si—Si bond in the internal region of the light-shielding film 2 is preferably 0.5 or more, and more preferably 0.55 or more. In addition, a ratio of an existence ratio of a SiₐN_{b} bond to a total existence ratio of a Si₃N₄ bond, the SiₐN_{b} bond, and a Si—Si bond in the internal region is preferably 0.5 or more, and more preferably 0.52 or more.

In addition, a ratio of an existence ratio of a Si₃N₄ bond to a total existence ratio of the Si₃N₄ bond, a SiₐN_{b} bond, and a Si—Si bond in the internal region is preferably 0.03 or more.

Meanwhile, when an existence ratio of a Si₃N₄ bond and/or a SiₐN_{b} bond in the internal region of the light-shielding film 2 is too large, an etching rate of the light-shielding film 2 with respect to dry etching in the film thickness direction largely decreases. In this case, it takes a long etching time to form a pattern on the light-shielding film 2, which makes time during which a sidewall of the pattern of the light-shielding film 2 is exposed to an etching gas long. As a result, side etching easily proceeds.

From this viewpoint, a ratio of a total existence ratio of a Si₃N₄ bond and a SiₐN_{b} bond to a total existence ratio of the Si₃N₄ bond, the SiₐN_{b} bond, and a Si—Si bond in the internal region of the light-shielding film 2 is preferably 0.8 or less, and more preferably 0.75 or less. In addition, a ratio of an existence ratio of a SiₐN_{b} bond to a total existence ratio of a Si₃N₄ bond, a SiₐN_{b} bond, and a Si—Si bond in the internal region is preferably 0.7 or less, and more preferably 0.65 or less. Furthermore, a ratio of an existence ratio of a Si₃N₄ bond to a total existence ratio of the Si₃N₄ bond, a SiₐN_{b} bond, and a Si—Si bond in the internal region is preferably 0.18 or less, and more preferably 0.15 or less.

The light-shielding film 2 is formed by sputtering, and it is possible to apply any sputtering such as DC sputtering, RF sputtering, or ion beam sputtering. In a case where a target having low conductivity (a silicon target, a silicon compound target which does not contain a metalloid element or contains a small amount of a metalloid element, or the like) is used, it is preferable to apply RF sputtering or ion beam sputtering, but in consideration of a film forming rate, it is more preferable to apply RF sputtering. A method of manufacturing the mask blank 10 preferably includes at least a step of forming the light-shielding film 2 on the transparent substrate 1 by reactive sputtering in a sputtering gas containing a nitrogen-based gas and a noble gas using a silicon target or a target made of a material containing silicon and one or more elements selected from a metalloid element and a nonmetallic element.

An optical density of the light-shielding film 2 is not determined only by a composition of the light-shielding film 2. A film density, a crystal state, and the like of the light-shielding film 2 are also factors that affect the optical density. Therefore, various conditions when the light-shielding film 2 is formed by reactive sputtering are adjusted, and the light-shielding film 2 is formed such that the optical density with respect to ArF exposure light falls within a prescribed range. Conditions for making the optical density of the light-shielding film 2 fall within a prescribed range are not limited to adjusting a ratio of a mixed gas of a noble gas and a reactive gas when the film is formed by reactive sputtering. There are a variety of conditions such as a pressure in a film forming chamber when the film is formed by reactive sputtering, power applied to a target, and a positional relationship such as a distance between the target and the transparent substrate. In addition, these film forming conditions are unique to a film forming apparatus, and are adjusted appropriately such that the light-shielding film 2 to be formed has a desired optical density.

Any gas can be applied as the nitrogen-based gas which is used as a sputtering gas when the light-shielding film 2 is formed, as long as the gas contains nitrogen. As described above, since the light-shielding film 2 preferably has a low oxygen content except for the surface layer thereof, it is preferable to apply a nitrogen-based gas not containing oxygen, and it is more preferable to apply a nitrogen gas (N₂ gas). In addition, the type of noble gas used as a sputtering gas when the light-shielding film 2 is formed is not limited, but argon, krypton, and xenon are preferably used. In addition, in order to alleviate a stress of the light-shielding film 2, helium and neon each having a small atomic weight can be actively taken into the light-shielding film 2.

In the mask blank 10 including the light-shielding film 2, the hard mask film 3 made of a material having etching selectivity with respect to an etching gas used for etching the light-shielding film 2 may be further layered on the light-shielding film 2. Since the light-shielding film 2 needs to ensure a predetermined optical density, there is a limit to reducing the thickness thereof. It is sufficient that the hard mask film 3 has a film thickness enough to function as an etching mask until dry etching for forming a pattern on the light-shielding film 2 immediately below the hard mask film 3 is finished, and basically, the hard mask film 3 is not limited in an optical characteristic. Therefore, the hard mask film 3 can be made significantly thinner than the light-shielding film 2. It is sufficient that the resist film 7 made of an organic material has a film thickness enough to function as an etching mask until dry etching for forming a pattern on the hard mask film 3 is finished, and therefore the resist film 7 can be made significantly thinner than a conventional resist film. Therefore, a problem such as resist pattern collapse can be suppressed.

The hard mask film 3 is preferably made of a chromium (Cr)-containing material. The chromium-containing material has particularly high dry etching resistance to dry etching using a fluorine-based gas such as SF₆. A thin film made of a chromium-containing material is generally patterned by dry etching using a mixed gas of a chlorine-based gas and oxygen gas. However, since this dry etching does not have so high anisotropy, etching (side etching) of a pattern in a sidewall direction easily proceeds during dry etching when a thin film made of a chromium-containing material is patterned.

In a case where a chromium-containing material is used for the light-shielding film, the film thickness of the light-shielding film 2 is relatively thick, and thus a problem of side etching occurs at the time of dry etching of the light-shielding film 2. However, in a case where a chromium-containing material is used as the hard mask film 3, the film thickness of the hard mask film 3 is relatively thin, and thus a problem caused by side etching hardly occurs.

Examples of the chromium-containing material include, in addition to chromium metal, a material which contains chromium and one or more elements selected from oxygen, nitrogen, carbon, boron, and fluorine, such as CrN, CrC, CrON, CrCO, or CrCON. When these elements are added to chromium metal, a film made of these tends to be a film having an amorphous structure, and thus surface roughness of the film and line edge roughness when the light-shielding film 2 is dry-etched are suppressed, which is preferable.

In addition, a material which contains chromium and one or more elements selected from oxygen, nitrogen, carbon, boron, and fluorine is preferably used as a material for forming the hard mask film 3 from a viewpoint of dry etching of the hard mask film 3.

A chromium-based material is etched with a mixed gas of a chlorine-based gas and an oxygen gas, but chromium metal has an etching rate that is not so high for this etching gas. By inclusion of one or more elements selected from oxygen, nitrogen, carbon, boron, and fluorine in addition to chromium, the etching rate for the etching gas of the mixed gas of a chlorine-based gas and oxygen gas can be increased.

Note that the hard mask film 3 made of CrCO is particularly preferable because the hard mask film 3 made of CrCO does not contain nitrogen that is likely to make side etching large with respect to dry etching using a mixed gas of a chlorine-based gas and an oxygen gas, but contains carbon that suppresses side etching, and further contains oxygen that improves an etching rate. One or more elements selected from indium, molybdenum, and tin may be contained in the chromium-containing material that forms the hard mask film 3. By inclusion of one or more elements selected from indium, molybdenum, and tin makes it possible to further increase the etching rate for the mixed gas of a chlorine-based gas and oxygen gas.

In the mask blank 10, the resist film 7 made of an organic material is preferably formed with a film thickness of 100 nm or less in contact with a surface of the hard mask film 3. In a case of a fine pattern corresponding to a DRAM hp 32 nm generation, a sub-resolution assist feature (SRAF) having a line width of 40 nm may be formed in a transfer pattern to be formed on the hard mask film 3. However, even in this case, since a cross-sectional aspect ratio of a resist pattern can be made as low as 1:2.5, it is possible to suppress collapse and detachment of the resist pattern during development, rinsing, and the like of the resist film. Note that, the resist film 7 more preferably has a film thickness of 80 nm or less. Note that the mask blank 10 does not have to include the resist film 7, or the resist film 7 may be formed by coating on the hard mask film 3 when a binary mask 100 is manufactured.

It is also possible to directly form the resist film 7 in contact with the light-shielding film 2 without forming the hard mask film 3 in the mask blank 10. In this case, the structure is simple, dry etching of the hard mask film 3 is unnecessary when a transfer mask is manufactured, and therefore the number of manufacturing steps can be reduced. Note that in this case, it is preferable to form the resist film 7 after performing surface treatment using hexamethyldisilazane (HMDS) or the like on the light-shielding film 2.

In addition, the mask blank 10 in the first embodiment of the present disclosure is a mask blank suitable for a binary mask, but use of the mask blank 10 is not limited to a binary mask, and the mask blank 10 can also be used as a mask blank for a Levenson type phase shift mask or a mask blank for a chromeless phase lithography (CPL) mask.

### [Transfer Mask]

FIGS. 1A-1D illustrate schematic cross-sectional views of a process of manufacturing the transfer mask (binary mask) 100 from the mask blank 10 according to an embodiment of the present disclosure.

A method of manufacturing the binary mask 100 illustrated in FIGS. 1A-1D uses the mask blank 10 described above, and includes: a step of forming a transfer pattern on the hard mask film 3 by dry etching; a step of forming a transfer pattern on the light-shielding film 2 by dry etching using the hard mask film 3 having the transfer pattern (hard mask pattern 3a) as a mask; and a step of removing the hard mask pattern 3a.

Hereinafter, an example of the method of manufacturing the binary mask 100 will be described according to the manufacturing process illustrated in FIGS. 1A-1D. Note that, in this example, a material containing silicon and nitrogen is applied to the light-shielding film 2, and a chromium-containing material is applied to the hard mask film 3.

First, the mask blank 10 in which the resist film 7 is formed in contact with the hard mask film 3 by a spin coating method is prepared (FIG. 1A). Next, a transfer pattern to be formed on the light-shielding film 2 is drawn by exposure on the resist film 7, and a predetermined treatment such as a development treatment is further performed to form a resist pattern 7a (refer to FIG. 1B).

Subsequently, dry etching using a fluorine-based gas such as a mixed gas of chlorine and oxygen is performed using the resist pattern 7a as a mask to form a pattern (hard mask pattern 3a) on the hard mask film 3 (refer to FIG. 1B). The chlorine-based gas is not particularly limited as long as the chlorine-based gas contains Cl, and examples thereof include Cl₂, SiCl₂, CHCl₃, CH₂Cl₂, BCl₃, and the like. In a case where a mixed gas of chlorine and oxygen is used, for example, a gas flow rate ratio therebetween is preferably Cl₂:O₂=4:1.

Next, the resist pattern 7a is removed by ashing or with a resist stripping solution (refer to FIG. 1C).

Subsequently, dry etching using a fluorine-based gas is performed using the hard mask pattern 3a as a mask to form a pattern (light-shielding pattern 2a) on the light-shielding film 2 (refer to FIG. 1C). Any gas containing F can be used as the fluorine-based gas, but SF₆ is preferable. In addition to SF₆, examples of the fluorine-based gas include CHF₃, CF₄, C₂F₆, C₄F₈, and the like, but a fluorine-based gas containing C has a relatively high etching rate with respect to the transparent substrate 1 formed of a glass material. SF₆ is preferable because SF₆ causes less damage to the transparent substrate 1. Note that, as illustrated in the drawing, it is more preferable to add He or the like to SF₆. In this step, as described in Examples and Comparative Example described later, a difference was generated in a side etching amount of the light-shielding pattern 2a depending on the magnitude of binding energy of a maximum peak in a Si₂p narrow spectrum in the internal region of the light-shielding film 2.

Thereafter, the hard mask pattern 3a is removed by dry etching using a mixed gas of chlorine and oxygen, and a predetermined treatment such as cleaning is performed to obtain the binary mask 100 (refer to FIG. 1D). Note that the step of removing the hard mask pattern 3a may be performed using a chromium etching solution. Here, examples of the chromium etching solution include a mixture containing ceric ammonium nitrate and perchloric acid.

The binary mask 100 manufactured by the manufacturing method illustrated in FIGS. 1A-1D is a binary mask including the light-shielding film 2 having a transfer pattern (light-shielding pattern 2a) on the transparent substrate 1.

The light-shielding film 2 having a transfer pattern (light-shielding pattern 2a) is made of a material containing silicon and nitrogen, and an internal region thereof has a maximum peak at a binding energy in a range in which a Si₂p narrow spectrum obtained by analysis by X-ray photoelectron spectroscopy is more than 100 eV and 101.5 eV or less. By manufacturing the binary mask 100 in this manner, the binary mask 100 has desired light-shielding performance, can suppress an increase in film thickness, can reduce a side etching amount generated by dry etching using a fluorine-based gas when the light-shielding pattern 2a is formed, and can form a fine pattern with high accuracy.

Note that, although the case where the binary mask 100 is a binary mask has been described here, the transfer mask of the present disclosure is not limited to a binary mask, and can also be applied to a Levenson type phase shift mask and a CPL mask. That is, in a case where the transfer mask of the present disclosure is a Levenson type phase shift mask, the light-shielding film of the present disclosure can be used as a light-shielding film of the Levenson type phase shift mask. In a case where the transfer mask of the present disclosure is a CPL mask, the light-shielding film of the present disclosure can be used mainly in a region including an outer light-shielding band.

Furthermore, the method of manufacturing a semiconductor device of the present disclosure includes performing exposure transfer of a transfer pattern to a resist film on a semiconductor substrate using the binary mask 100 described above or the binary mask 100 manufactured using the mask blank 10 described above.

Since the mask blank 10 and the binary mask 100 in the present embodiment have the above-described effects, when the binary mask 100 is set on a mask stage of an exposure apparatus using an ArF excimer laser as exposure light and exposure transfer of a transfer pattern is performed to a resist film on a semiconductor device, the transfer pattern can be transferred to the resist film on the semiconductor device with high CD accuracy. Therefore, in a case where a lower layer film of the pattern of the resist film is dry-etched using the pattern of the resist film as a mask to form a circuit pattern, it is possible to form a highly accurate circuit pattern without a wiring short circuit or disconnection due to insufficient accuracy.

### Second Embodiment

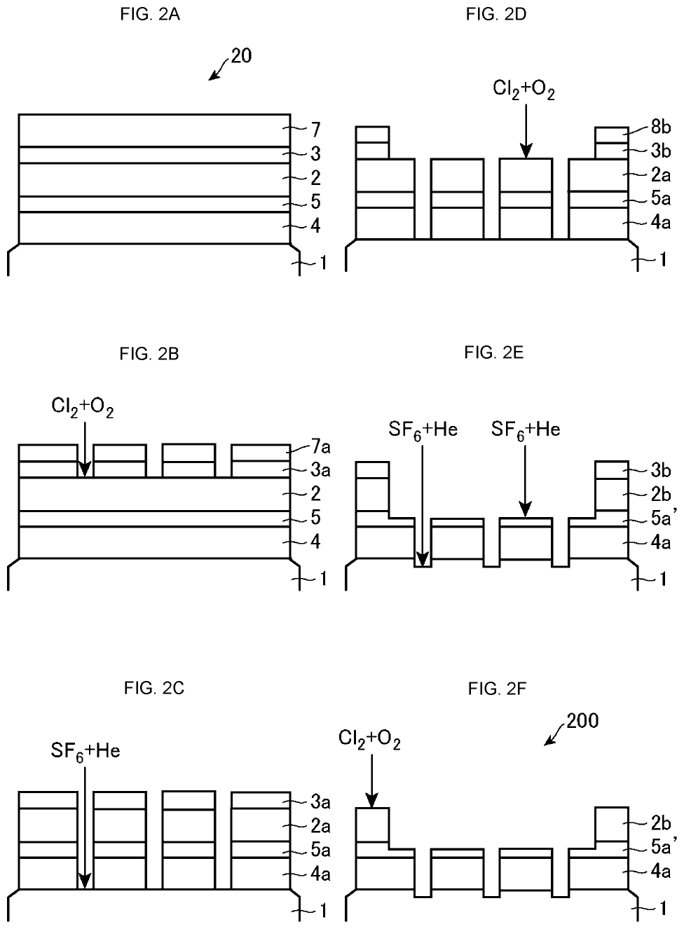

A mask blank according to a second embodiment of the present disclosure uses a phase shift film that imparts a predetermined transmittance and phase difference to exposure light as a pattern forming thin film, and is used for manufacturing a phase shift mask (transfer mask). FIGS. 2A-2F are cross-sectional views illustrating a configuration of the mask blank according to the second embodiment of the present disclosure and a phase shift mask manufacturing process using the mask blank. FIG. 2A is a cross-sectional view illustrating a configuration of a mask blank 20 according to the second embodiment of the present disclosure.

The mask blank 20 illustrated in FIG. 2A has a structure in which a phase shift film (pattern forming thin film) 4, an etching stopper film 5, a light-shielding film 2, a hard mask film 3, and a resist film 7 are layered in this order on a main surface of a transparent substrate 1. Note that the same reference numerals are used for the same components as those of the mask blank of the first embodiment, and description thereof is omitted here.

The phase shift film 4 is made of a material to be etched by dry etching using a gas containing fluorine. Examples of the material having such a characteristic include a material containing a transition metal and silicon in addition to a material containing silicon. Examples of the transition metal contained in the phase shift film 4 include any one metal selected from molybdenum (Mo), tantalum (Ta), tungsten (W), titanium (Ti), chromium (Cr), nickel (Ni), vanadium (V), zirconium (Zr), ruthenium (Ru), rhodium (Rh), niobium (Nb), palladium (Pd), and the like, and alloys of these metals.

The phase shift film 4 preferably has a function (transmittance) of transmitting exposure light with a transmittance of 1% or more and a function of generating a phase difference of 150 degrees or more and 210 degrees or less between exposure light that has passed through the phase shift film 4 and exposure light that has passed through air by the same distance as the thickness of the phase shift film 4. The transmittance of the phase shift film 4 is more preferably 2% or more. The transmittance of the phase shift film 4 is preferably 40% or less, and more preferably 30% or less.

The thickness of the phase shift film 4 is preferably 80 nm or less, and more preferably 70 nm or less. In order to reduce a fluctuation range of a best focus depending on a pattern line width of the phase shift pattern, the thickness of the phase shift film 4 is particularly preferably 65 nm or less. The thickness of the phase shift film 4 is preferably 50 nm or more. This is because a thickness of 50 nm or more is necessary in order to form the phase shift film 4 using an amorphous material and to make the phase difference of the phase shift film 4 150 degrees or more.

In the phase shift film 4, a refractive index n of the phase shift film with respect to exposure light (ArF exposure light) is preferably 1.9 or more, and more preferably 2.0 or more in order to satisfy various conditions regarding the optical characteristics and the film thickness. In addition, the refractive index n of the phase shift film 4 is preferably 3.1 or less, and more preferably 2.7 or less. An extinction coefficient k of the phase shift film 4 with respect to ArF exposure light is preferably 0.26 or more, and more preferably 0.29 or more. In addition, the extinction coefficient k of the phase shift film 4 is preferably 0.62 or less, and more preferably 0.54 or less.

The mask blank 20 of the second embodiment includes the etching stopper film 5 between the phase shift film 4 and the light-shielding film 2. The etching stopper film 5 is preferably made of a SiO-based material containing silicon and oxygen. As a result, an etching stopper function for the light-shielding film 2 made of a material containing silicon and nitrogen can be ensured to a certain extent, and patterning with a fluorine-based gas can be performed. The film thickness of the etching stopper film 5 is preferably 3 nm or more as long as the etching stopper function can be ensured. Meanwhile, the etching stopper film 5 forms a phase shift pattern (transfer pattern) in a stack with the phase shift film 4. The etching stopper film 5 has a smaller refractive index n and a smaller extinction coefficient k with respect to exposure light than the phase shift film 4. Therefore, when the film thickness of the etching stopper film 5 is increased, the film thickness of the phase shift film 4 cannot be reduced by the amount of the increase in the film thickness of the etching stopper film 5. From this viewpoint, the film thickness of the etching stopper film 5 is preferably 15 nm or less, and more preferably 10 nm or less.

The light-shielding film 2 of the second embodiment has the same configuration as the light-shielding film 2 of the first embodiment, but ensures desired light-shielding performance in the stack with the phase shift film 4 and the etching stopper film 5. That is, in the case of the second embodiment, an optical density of the stack of the phase shift film 4, the etching stopper film 5, and the light-shielding film 2 with respect to ArF exposure light is preferably 2.5 or more, and more preferably 3.0 or more. In addition, the optical density of the stack of the phase shift film 4, the etching stopper film 5, and the light-shielding film 2 with respect to ArF exposure light is preferably 4.0 or less, and more preferably 3.5 or less. In addition, since the optical density required for the light-shielding film 2 of the second embodiment is smaller than the optical density required for the light-shielding film 2 of the first embodiment, the film thickness required for the light-shielding film 2 of the second embodiment is also smaller. The thickness of the light-shielding film 2 of the second embodiment is preferably 70 nm or less, and more preferably 60 nm or less. In addition, the thickness of the light-shielding film 2 is preferably 30 nm or more, and more preferably 35 nm or more.

### [Transfer Mask (Phase Shift Mask) and Manufacture Thereof]

A transfer mask (phase shift mask) 200 (refer to FIG. 2F) according to the second embodiment has a structure in which a phase shift pattern 4a which is a phase shift film having a transfer pattern and a light-shielding pattern 2b which is a light-shielding film having a pattern including a light-shielding band are layered in this order on a main surface of the transparent substrate 1. The phase shift pattern 4a is made of a material to be etched by dry etching using a fluorine-containing gas. The light-shielding pattern 2b is made of a material containing silicon and nitrogen. An internal region of the light-shielding pattern 2b has a maximum peak at a binding energy in a range in which a Si₂p narrow spectrum obtained by analysis by X-ray photoelectron spectroscopy is more than 100 eV and 101.5 eV or less.

A method of manufacturing the phase shift mask 200 according to the second embodiment uses the mask blank 20 described above, and includes: a step of continuously performing, at one time, a treatment of forming a transfer pattern on the light-shielding film 2 by dry etching using a fluorine-based gas and a treatment of forming a transfer pattern on the phase shift film 4 by dry etching using the fluorine-based gas with the light-shielding film 2 having the transfer pattern as a mask; and a step of forming a pattern (a light-shielding band, a light-shielding patch, and the like) including a light-shielding band on the light-shielding film 2 by dry etching. Hereinafter, a method of manufacturing the phase shift mask 200 of the second embodiment will be described according to the manufacturing process illustrated in FIGS. 2A-2F.

First, the mask blank 20 in which the resist film 7 is formed in contact with the hard mask film 3 by a spin coating method is prepared (FIG. 2A). Next, a first pattern that is a transfer pattern (phase shift pattern) to be formed on the phase shift film 4 is drawn with an electron beam on the resist film 7, and a predetermined treatment such as a development treatment is further performed to form a first resist pattern 7a having the phase shift pattern (refer to FIG. 2B). Subsequently, dry etching using a fluorine-based gas such as a mixed gas of chlorine and oxygen is performed using the first resist pattern 7a as a mask to form a first pattern (a hard mask pattern 3a) on the hard mask film 3 (refer to FIG. 2B).

Next, after the resist pattern 7a is removed, dry etching using a fluorine-based gas is performed using the hard mask pattern 3a as a mask to form a first pattern (a light-shielding pattern 2a) on the light-shielding film 2 (refer to FIG. 2C). Subsequently, dry etching using a fluorine-based gas is performed using the light-shielding pattern 2a as a mask to form a first pattern (an etching stopper pattern 5a and a phase shift pattern 4a) on the etching stopper film 5 and the phase shift film 4 (refer to FIG. 2C). In this step, as described in Examples and Comparative Example described later, a difference was generated in a side etching amount of the light-shielding pattern 2a depending on the magnitude of binding energy of a maximum peak in a Si₂p narrow spectrum in the internal region of the light-shielding film 2.

When a transfer pattern (phase shift pattern 4a) is formed on the phase shift film by dry etching using a fluorine-based gas, a sidewall of the light-shielding pattern 2a is exposed to an etching gas, and side etching occurs. In a case of the light-shielding film 2 in which large side etching occurs as in a conventional light-shielding film, an upper surface of the etching stopper pattern 5a immediately below a region where a sidewall is reduced by side etching is etched by an etching gas. Furthermore, etching from an upper surface of the phase shift pattern 4a also proceeds, and thus it is difficult to form a highly accurate and fine transfer pattern on the phase shift film 4.

On the other hand, in the second embodiment, by using the light-shielding film 2 in which the side etching amount is reduced, etching of the upper surface of the etching stopper pattern 5a is suppressed. As a result, a highly accurate and fine transfer pattern (phase shift pattern 4a) can be formed on the phase shift film 4.

Next, a resist film is formed on the mask blank 20 by a spin coating method. Thereafter, a second pattern that is a pattern (light-shielding pattern) to be formed on the light-shielding film 2 is drawn by an electron beam on the resist film, and a predetermined treatment such as a development treatment is further performed to form a second resist pattern 8b having the light-shielding pattern (refer to FIG. 2D). Here, since the second pattern is a relatively large pattern, instead of drawing using an electron beam, exposure drawing using a laser beam by a laser drawing apparatus having a high throughput can be performed.

Subsequently, dry etching using a mixed gas of a chlorine-based gas and oxygen gas is performed using the second resist pattern 8b as a mask to form a second pattern (hard mask pattern 3b) on the hard mask film 3 (refer to FIG. 2D). Furthermore, the second resist pattern 8b is removed by ashing or with a resist stripping solution.

Subsequently, dry etching using a fluorine-based gas is performed using the hard mask pattern 3b as a mask to form a second pattern (light-shielding pattern 2b) on the light-shielding film 2 (refer to FIG. 2E). At this time, the etching stopper pattern 5a is slightly etched by the fluorine-based gas to reduce a thickness thereof, thus forming an etching stopper pattern 5a′. The etching stopper pattern 5a′ can suppress further etching of the phase shift pattern 4a. Note that an exposed portion of the transparent substrate 1 is also slightly etched by the fluorine-based gas, but fluctuation of a phase difference due to this etching is small. Therefore, a desired phase difference can be ensured.

Thereafter, the hard mask pattern 3b is removed by dry etching using a mixed gas of chlorine and oxygen, and a predetermined treatment such as cleaning is performed to obtain the phase shift mask 200 (refer to FIG. 2F).

The phase shift mask 200 manufactured by the manufacturing method illustrated in FIGS. 2A-2F is the phase shift mask 200 including the phase shift film 4 (phase shift pattern 4a) having a transfer pattern and the light-shielding film 2 (light-shielding pattern 2b) having a pattern including a light-shielding band on the transparent substrate 1.

The light-shielding film 2 (light-shielding pattern 2b) having a pattern including a light-shielding band is made of a material containing silicon and nitrogen, and an internal region thereof has a maximum peak at a binding energy in a range in which a Si2p narrow spectrum obtained by analysis by X-ray photoelectron spectroscopy is more than 100 eV and 101.5 eV or less. By manufacturing the phase shift mask 200 in this manner, the phase shift mask 200 has desired light-shielding performance, can suppress an increase in film thickness, can reduce a side etching amount generated by dry etching when the light-shielding pattern 2a is formed, and can form a fine pattern with high accuracy. As a result, a fine and highly accurate transfer pattern can be formed on the phase shift film 4.

Furthermore, a method of manufacturing a semiconductor device of the present disclosure includes performing exposure transfer of a transfer pattern to a resist film on a semiconductor substrate using the phase shift mask 200 described above or the phase shift mask 200 manufactured using the mask blank 20 described above.

Since the mask blank 20 and the phase shift mask 200 in the present embodiment have the above-described effects, when the phase shift mask 200 is set on a mask stage of an exposure apparatus using an ArF excimer laser as exposure light and exposure transfer of a transfer pattern is performed to a resist film on a semiconductor device, the transfer pattern can be transferred to the resist film on the semiconductor device with high CD accuracy. Therefore, in a case where a lower layer film under the pattern of the resist film is dry-etched using the pattern of the resist film as a mask to form a circuit pattern, it is possible to form a highly accurate circuit pattern without a wiring short circuit or disconnection due to insufficient accuracy.

### Third Embodiment

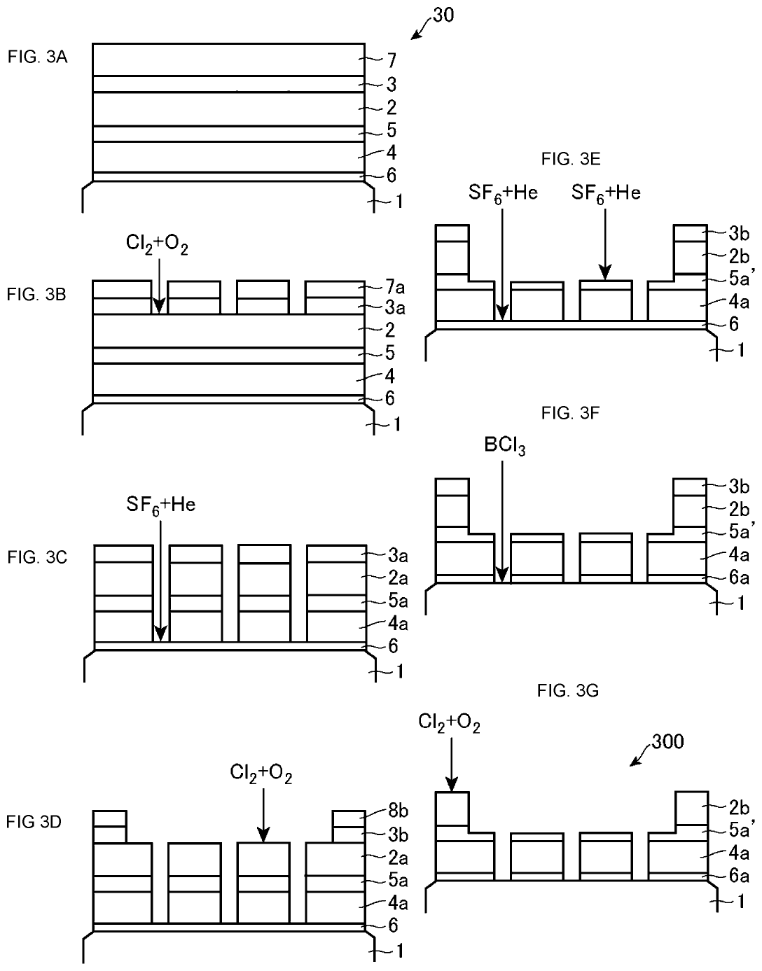

A mask blank according to a third embodiment of the present disclosure uses a phase shift film that imparts a predetermined transmittance and phase difference to exposure light as a pattern forming thin film, and is used for manufacturing a phase shift mask (transfer mask). FIGS. 3A-3G are cross-sectional views illustrating a configuration of the mask blank according to the third embodiment of the present disclosure and a phase shift mask manufacturing process using the mask blank. FIG. 3A is a cross-sectional view illustrating a configuration of a mask blank 30 according to the third embodiment of the present disclosure.

The mask blank 30 illustrated in FIG. 3A has a structure in which an etching stopper film 6, a phase shift film (pattern forming thin film) 4, an etching stopper film 5, a light-shielding film 2, a hard mask film 3, and a resist film 7 are layered in this order on a main surface of a transparent substrate 1. Note that the same reference numerals are used for the same components as those of the mask blank of the first or second embodiment, and description thereof is omitted here.

The mask blank 30 of the third embodiment includes the etching stopper film 6 between the transparent substrate 1 and the phase shift film 4. The etching stopper film 6 is preferably made of an HfO-based material containing hafnium and oxygen. As a result, an etching stopper function for the transparent substrate 1 made of a material containing silicon and oxygen can be ensured, and digging of the transparent substrate 1 by a fluorine-based gas can be suppressed. The film thickness of the etching stopper film 6 may be any thickness as long as the etching stopper function can be ensured, and is preferably 3 nm or more. Meanwhile, the etching stopper film 6 forms a phase shift pattern (transfer pattern) in a stack with the phase shift film 4 and the etching stopper film 5. The etching stopper film 6 has a smaller extinction coefficient k with respect to exposure light than the phase shift film 4. Therefore, when the film thickness of the etching stopper film 5 is increased, the film thickness of the phase shift film 4 cannot be reduced by the amount of the increase in the film thickness of the etching stopper film 5. From this viewpoint, the film thickness of the etching stopper film 5 is preferably 15 nm or less, and more preferably 10 nm or less.

The light-shielding film 2 of the third embodiment has the same configuration as that of the light-shielding film 2 of the first embodiment, but ensures desired light-shielding performance in the stack with the etching stopper film 6, the phase shift film 4, and the etching stopper film 5, that is, in the case of the third embodiment, an optical density of the stack of the etching stopper film 6, the phase shift film 4, the etching stopper film 5, and the light-shielding film 2 with respect to ArF exposure light is preferably 2.5 or more, and more preferably 3.0 or more. In addition, the optical density of the stack of the etching stopper film 6, the phase shift film 4, the etching stopper film 5, and the light-shielding film 2 with respect to ArF exposure light is preferably 4.0 or less, and more preferably 3.5 or less. In addition, since the optical density required for the light-shielding film 2 is smaller than the optical density required for the light-shielding film 2 of the first embodiment, the film thickness required for the light-shielding film 2 is also smaller. The thickness of the light-shielding film 2 of the third embodiment is preferably 70 nm or less, and more preferably 60 nm or less. In addition, the thickness of the light-shielding film 2 is preferably 30 nm or more, and more preferably 35 nm or more.

### [Transfer Mask (Phase Shift Mask) and Manufacture Thereof]

A transfer mask (phase shift mask) 300 (refer to FIG. 3G) according to the third embodiment has a structure in which a phase shift pattern 4a which is a phase shift film having a transfer pattern and a light-shielding pattern 2b which is a light-shielding film having a pattern including a light-shielding band are layered in this order on a main surface of the transparent substrate 1. The phase shift pattern 4a is made of a material to be etched by dry etching using a fluorine-containing gas. The light-shielding pattern 2b is made of a material containing silicon and nitrogen. An internal region of the light-shielding pattern 2b has a maximum peak at a binding energy in a range in which a Si₂p narrow spectrum obtained by analysis by X-ray photoelectron spectroscopy is more than 100 eV and 101.5 eV or less.

A method of manufacturing the phase shift mask 300 according to the third embodiment uses the mask blank 30 described above, and includes: a step of continuously performing, at one time, a treatment of forming a transfer pattern on the light-shielding film 2 by dry etching using a fluorine-based gas and a treatment of forming a transfer pattern on the phase shift film 4 by dry etching using the fluorine-based gas with the light-shielding film 2 having the transfer pattern as a mask; and a step of forming a pattern (light-shielding band, light-shielding patch, and the like) including a light-shielding band on the light-shielding film 2 by dry etching. Hereinafter, a method of manufacturing the phase shift mask 300 of the third embodiment will be described according to the manufacturing process illustrated in FIGS. 3A-3G.

First, the mask blank 30 in which the resist film 7 is formed in contact with the hard mask film 3 by a spin coating method is prepared (FIG. 3A). Next, a first pattern that is a transfer pattern (phase shift pattern) to be formed on the phase shift film 4 is drawn with an electron beam on the resist film 7, and a predetermined treatment such as a development treatment is further performed to form a first resist pattern 7a having the phase shift pattern (refer to FIG. 3B). Subsequently, dry etching using a chlorine-based gas such as a mixed gas of chlorine and oxygen is performed using the first resist pattern 7a as a mask to form a first pattern (a hard mask pattern 3a) on the hard mask film 3 (refer to FIG. 3B).

Next, after the resist pattern 7a is removed, dry etching using a fluorine-based gas is performed using the hard mask pattern 3a as a mask to form a first pattern (a light-shielding pattern 2a) on the light-shielding film 2 (refer to FIG. 3C). Subsequently, dry etching using a fluorine-based gas is performed using the light-shielding pattern 2a as a mask to form a first pattern (an etching stopper pattern 5a and a phase shift pattern 4a) on the etching stopper film 5 and the phase shift film 4 (refer to FIG. 3C). In this step, as described in Examples and Comparative Example described later, a difference was generated in a side etching amount of the light-shielding pattern 2a depending on the magnitude of binding energy of a maximum peak in a Si₂p narrow spectrum in the internal region of the light-shielding film 2.

In addition, the mask blank 30 of the present embodiment includes the etching stopper film 6 on the transparent substrate 1. The etching stopper film 6 has an etching stopper function for a fluorine-based gas, and therefore can suppress exposure of a surface of the transparent substrate 1 to the fluorine-based gas.

Also in the third embodiment, as in the second embodiment, by using the light-shielding film 2 in which the side etching amount is reduced, etching of the upper surface of the etching stopper pattern 5a is suppressed. As a result, a highly accurate and fine transfer pattern (phase shift pattern 4a) can be formed on the phase shift film 4.

Next, a resist film is formed on the mask blank 30 by a spin coating method. Thereafter, a second pattern that is a pattern (light-shielding pattern) to be formed on the light-shielding film 2 is drawn by an electron beam on the resist film, and a predetermined treatment such as a development treatment is further performed to form a second resist pattern 8b having the light-shielding pattern (refer to FIG. 3D). Here, since the second pattern is a relatively large pattern, instead of drawing using an electron beam, exposure drawing using a laser beam by a laser drawing apparatus having a high throughput can be performed.

Subsequently, dry etching using a mixed gas of a chlorine-based gas and oxygen gas is performed using the second resist pattern 8b as a mask to form a second pattern (hard mask pattern 3b) on the hard mask film 3 (refer to FIG. 3D). Furthermore, the second resist pattern 8b is removed by ashing or with a resist stripping solution.

Subsequently, dry etching using a fluorine-based gas is performed using the hard mask pattern 3b as a mask to form a second pattern (light-shielding pattern 2b) on the light-shielding film 2 (refer to FIG. 3E). At this time, while the etching stopper pattern 5a is slightly etched by the fluorine-based gas to form an etching stopper pattern 5a′ having a reduced thickness, the etching stopper pattern 5a′ can suppress further etching of the phase shift pattern 4a. Note that the etching stopper film 6 is formed on the transparent substrate 1, and therefore it is possible to suppress exposure of the transparent substrate 1 to the fluorine-based gas.

Then, dry etching using a boron trichloride gas (BCl₃ gas) is performed to form a second pattern (etching stopper pattern 6a) on the etching stopper film 6. As a result, a transmittance of a transparent portion where the phase shift pattern 4a is not formed can be increased. Note that as the dry etching used in this step, a noble gas such as helium may be contained in the boron trichloride gas.

Thereafter, the hard mask pattern 3b is removed by dry etching using a mixed gas of chlorine and oxygen, and a predetermined treatment such as cleaning is performed to obtain the phase shift mask 300 (refer to FIG. 3G).

The phase shift mask 300 manufactured by the manufacturing method illustrated in FIGS. 3A-3G is the phase shift mask 300 including the phase shift film 4 (phase shift pattern 4a) having a transfer pattern and the light-shielding film 2 (light-shielding pattern 2b) including a light-shielding band on the transparent substrate 1.

The light-shielding film 2 (light-shielding pattern 2a) including a light-shielding band is made of a material containing silicon and nitrogen, and an internal region thereof has a maximum peak at a binding energy in a range in which a Si₂p narrow spectrum obtained by analysis by X-ray photoelectron spectroscopy is more than 100 eV and 101.5 eV or less. By manufacturing the phase shift mask 300 in this manner, the phase shift mask 300 has desired light-shielding performance, can suppress an increase in film thickness, can reduce a side etching amount generated by dry etching when the light-shielding pattern 2a is formed, and can form a fine pattern with high accuracy. As a result, a fine and highly accurate transfer pattern can be formed on the phase shift film 4.

Furthermore, the method of manufacturing a semiconductor device of the present disclosure includes performing exposure transfer of a transfer pattern to a resist film on a semiconductor substrate using the phase shift mask 300 described above or the phase shift mask 300 manufactured using the mask blank 30 described above.

Since the mask blank 30 and the phase shift mask 300 in the present embodiment have the above-described effects, when the phase shift mask 200 is set on a mask stage of an exposure apparatus using an ArF excimer laser as exposure light and exposure transfer of a transfer pattern is performed to a resist film on a semiconductor device, the transfer pattern can be transferred to the resist film on the semiconductor device with high CD accuracy. Therefore, in a case where a lower layer film under the pattern of the resist film is dry-etched using the pattern of the resist film as a mask to form a circuit pattern, it is possible to form a highly accurate circuit pattern without a wiring short circuit or disconnection due to insufficient accuracy.

### EXAMPLES

Hereinafter, the embodiments of the present disclosure will be described more specifically with reference to Examples.

### Example 1

### [Manufacture of Mask Blank]

A transparent substrate 1 made of synthetic quartz glass and having a main surface dimension of about 152 mm×about 152 mm and a thickness of about 6.25 mm was prepared. End surfaces and main surfaces of the transparent substrate 1 were polished so as to have a predetermined surface roughness, and then the transparent substrate 1 was subjected to a predetermined cleaning treatment and drying treatment.

Next, the transparent substrate 1 was placed in a single wafer type RF sputtering apparatus, and an etching stopper film 6 containing hafnium and oxygen was formed with a film thickness of 3 nm by sputtering (RF sputtering) using an HfO₂ target and using an argon (Ar) gas as a sputtering gas.

Then, by performing reactive sputtering (RF sputtering) by an RF power supply using a silicon (Si) target in a mixed gas of argon (Ar), nitrogen (N₂), and helium (He) as a sputtering gas, a phase shift film 4 made of silicon and nitrogen was formed on the etching stopper film 6 with a thickness of 56 nm. Only the phase shift film 4 was formed on another transparent substrate 1, and the phase shift film 4 was analyzed by X-ray photoelectron spectroscopy. As a result, it was confirmed that the contents of the constituent elements of the phase shift film 4 were Si: 46.9 atom % and N: 53.1 atom %. Subsequently, an etching stopper film 5 made of silicon and oxygen was formed with a thickness of 9 nm by sputtering (RF sputtering) using a silicon oxide (SiO₂) target in an argon (Ar) gas as a sputtering gas. The phase shift film 4 and the etching stopper film 5 were formed on another transparent substrate 1, and a transmittance and a phase difference of the stack of the phase shift film 4 and the etching stopper film 5 with respect to light having a wavelength of 193 nm were measured using a phase shift amount measuring device (MPM 193 manufactured by Lasertec Co., Ltd). As a result, the transmittance was 21.4%, and the phase difference was 172 degrees.

Then, by performing reactive sputtering (DC sputtering) by a DC power supply using a silicon (Si) target in a mixed gas of krypton (Kr), nitrogen (N₂), and helium (He) (flow rate ratio Kr: N₂:He=5:2:25) as a sputtering gas, a light-shielding film 2 made of silicon and nitrogen was formed with a thickness of 50 nm on the transparent substrate 1. In addition, power of the DC power supply during sputtering was 1500 W.

Then, a hard mask film (CrOC film) 3 made of chromium, oxygen, and carbon was formed with a thickness of 9 nm. Specifically, the hard mask film 3 was formed by reactive sputtering (DC sputtering) using a chromium (Cr) target in a mixed gas of argon (Ar), carbon dioxide (CO₂), and helium (He) as a sputtering gas. Only the hard mask film 3 was formed on another transparent substrate 1, and the hard mask film 3 was analyzed by X-ray photoelectron spectroscopy (with RBS correction). As a result, it was confirmed that the contents of the constituent elements of the hard mask film 3 were Cr: 71 atom %, O: 15 atom %, and C: 14 atom % on average.

Finally, a resist film 7 was formed with a thickness of 80 nm by a spin coating method to manufacture a mask blank 30 of Example 1.

An optical density (OD) of the stack of the etching stopper film 6, the phase shift film 4, the light-shielding film 2, the etching stopper film 5, and the hard mask film 3 at a wavelength of 193 nm was measured using a spectrophotometer (Cary 4000 manufactured by Agilent Technologies), and was found to be 3.0 or more. From this result, the mask blank 30 of Example 1 has required high light-shielding performance.

Another etching stopper film, phase shift film, etching stopper film, and light-shielding film were formed on a main surface of another transparent substrate under the same film forming conditions as in Example 1. Next, X-ray photoelectron spectroscopy was performed on the light-shielding film on the another transparent substrate. In this X-ray photoelectron spectroscopy, by repeating a step including: irradiating a surface of the light-shielding film with an X-ray (AlKα ray: 1486 eV); measuring an intensity of photoelectrons emitted from the light-shielding film; digging the light-shielding film by Ar gas sputtering at an Ar target voltage of 2.0 kV at a sputtering rate of about 5 nm/min (in terms of SiO₂); irradiating the light-shielding film in a dug region with the X-ray; and measuring an intensity of photoelectrons emitted from the dug region, an Sip narrow spectrum at each depth of the light-shielding film was acquired. (The same applies to the following Example 2 and Comparative Example 1).

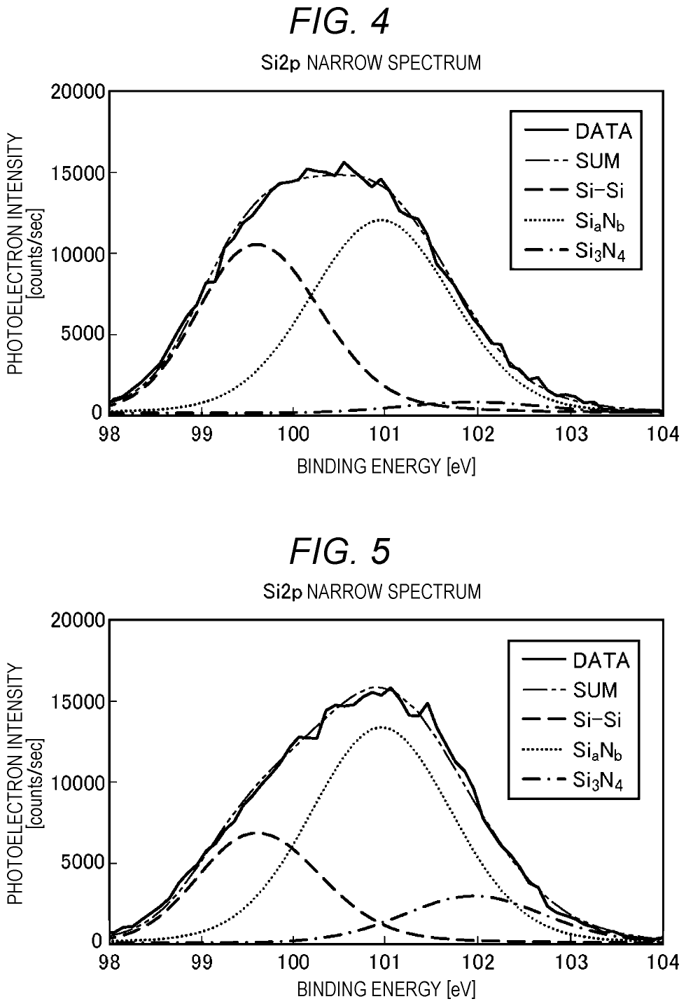

FIG. 4 is a diagram illustrating a Si₂p narrow spectrum at a predetermined depth within a range of an internal region in results obtained by performing X-ray photoelectron spectroscopy on the light-shielding film of the mask blank according to Example 1. As illustrated in the drawing, a maximum peak in the Si₂p narrow spectrum of Example 1 was 100.6 eV, which satisfied a range of more than 100 eV and 101.5 eV or less.

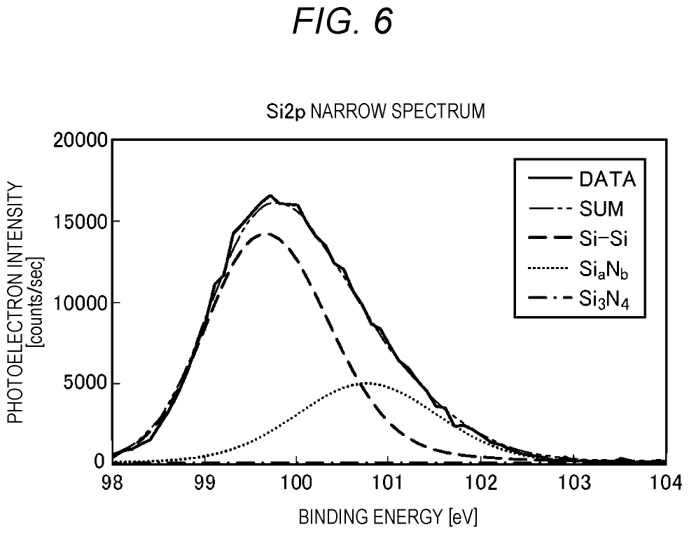

In addition, the acquired Si₂p narrow spectrum includes each of peaks of a Si—Si bond, a SiₐN_{b} bond, and a Si₃N₄ bond. Then, the peak position of each of the Si—Si bond, the SiₐN_{b} bond, and the Si₃N₄ bond and full widths at half maximum (FWHM) were fixed, and peak separation was performed. Specifically, the peak position of the Si—Si bond was set to 99.75 eV, the peak position of the SiₐN_{b} bond was set to 101.05 eV, the peak position of the Si₃N₄ bond was set to 102.25 eV, and the full width at half maximum FWHM of each of the bonds was set to 1.71, and peak separation was performed. Note that, in the drawing, a spectrum obtained by actual measurement is referred to as “DATA”, and a sum of spectra obtained by peak separation is referred to as “SUM” (The same applies to FIGS. 5 and 6). As can be seen from these drawings, the spectra of “DATA” and “SUM” almost coincide with each other, and it can be said that accuracy of peak separation is favorable.

Then, for each spectrum of the Si—Si bond, SiₐN_{b} bond, and Si₃N₄ bond which was obtained by separating peaks, an area was calculated by subtracting a background calculated by an algorithm of a known method included in an analyzer, and a ratio of the number of existing Si—Si bonds, a ratio of the number of SiₐN_{b} bonds, and a ratio of the number of Si₃N₄ bonds were calculated based on the areas which were obtained by calculating, respectively.

As a result, the ratio of the number of existing Si—Si bonds was 0.420, the ratio of the number of existing SiₐN_{b} bonds was 0.548, and the ratio of the number of existing Si₃N₄ bonds was 0.032. That is, all of the conditions were satisfied that, in the internal region, the ratio of the total existence ratio of the Si₃N₄ bond and the SiₐN_{b} bond to the total existence ratio of the Si₃N₄ bond, the SiₐN_{b} bond, and the Si—Si bond is 0.5 or more, that the ratio of the existence ratio of the SiₐN_{b} bond to the total existence ratio of the Si₃N₄ bond, the SiₐN_{b} bond, and the Si—Si bond is 0.5 or more, and that the ratio of the existence ratio of the Si₃N₄ bond to the total existence ratio of the Si₃N₄ bond, the SiₐN_{b} bond, and the Si—Si bond is 0.03 or more.

In addition, a ratio of the number of existing Si—Si bonds, a ratio of the number of existing SiₐN_{b} bonds, and a ratio of the number of existing Si₃N₄ bonds were calculated by the same procedure for each Si₂p narrow spectrum at a depth corresponding as that for the internal region of the light-shielding film, other than the depth illustrated in FIG. 4, among the acquired Si₂p narrow spectra at depths of the light-shielding film. As a result, the ratio of the number of existing Si—Si bonds, the ratio of the number of existing Si No bonds, and the ratio of the number of existing Si₃N₄ bonds at any depth of the internal region had the same tendency as that of the ratio of the number of existing Si-si bonds, the ratio of the number of existing SiₐN_{b} bonds, and the ratio of the number of existing Si₃N₄ bonds at the depth illustrated in FIG. 4, respectively. In addition, all of the ratios satisfied the three conditions regarding the ratio of the number of existing bonds described above.

In addition, from the results of the X-ray photoelectron spectroscopy, it was found that an average composition of the internal region of the light-shielding film was Si:N: 0=61.2:38.1:0.7 (atom % ratio).

### [Manufacture of Transfer Mask]

Next, using the mask blank 30 of Example 1, the transfer mask (phase shift mask) 300 of Example 1 was manufactured by the procedure of the third embodiment.

In addition, using another mask blank 30 of Example 1, the first pattern (the hard mask pattern 3a, the light-shielding pattern 2a, the etching stopper pattern 5a, and the phase shift pattern 4a) was formed on the hard mask film 3, the light-shielding film 2, the etching stopper film 5, and the phase shift film 4 (refer to FIG. 3C), and a cross section thereof was observed with a cross-sectional TEM. As a result, a side surface of the light-shielding pattern 2a was located on a side of 3.1 nm with respect to a side surface of the hard mask pattern 3a. That is, a side etching amount of the light-shielding pattern 2a was within an allowable range.

As described above, it can be said that the light-shielding film 2 of the mask blank 30 of Example 1 has desired light-shielding performance, can suppress an increase in film thickness, and can reduce the side etching amount generated by dry etching when a pattern is formed.

In addition, also in the method of manufacturing the phase shift mask 200 of the second embodiment, a first pattern (a hard mask pattern 3a, a light-shielding pattern 2a, an etching stopper pattern 5a, and a phase shift pattern 4a) is formed on the hard mask film 3, the light-shielding film 2, the etching stopper film 5, and the phase shift film 4 in the same step as that of the phase shift mask 300 of the third embodiment (refer to FIGS. 2A to 2C). Therefore, it can be said that the light-shielding film 2 has desired light-shielding performance, can suppress an increase in film thickness, and can reduce the side etching amount generated by dry etching during a pattern formation when the light-shielding film 2 of Example 1 is applied to the mask blank 20 having the configuration of the second embodiment.

In addition, in the method of manufacturing the binary mask 100 of the first embodiment, although the film thickness itself of the light-shielding film 2 is larger than the film thickness of that of the third embodiment, etching time for forming the first pattern is shorter than that in the third embodiment since a target for forming the first pattern is only the light-shielding film. Therefore, it can be said that the light-shielding film 2 has desired light-shielding performance, can suppress an increase in film thickness, and can reduce the side etching amount generated by dry etching during a pattern formation when the light-shielding film 2 of Example 1 is applied to the mask blank 20 having the configuration of the second embodiment.

Next, the phase shift mask 300 of Example 1 was subjected to simulation of a transfer image at the time of exposure transfer to a resist film on a semiconductor device with exposure light of a wavelength of 193 nm using AIMS 193 (manufactured by Carl Zeiss AG). Verification of an exposure transfer image of this simulation indicated that design specifications were sufficiently satisfied. From this result, it can be said that a circuit pattern finally formed on the semiconductor device can be formed with high accuracy when the phase shift mask 300 of Example 1 is set on a mask stage of an exposure apparatus and exposure transfer is performed to a resist film on the semiconductor device. Therefore, it can be said that the phase shift mask 300 manufactured by the method of manufacturing a transfer mask of Example 1 is a transfer mask with high transfer accuracy.

### Example 2

### [Manufacture of Mask Blank]

A mask blank 30 of Example 2 was manufactured by the same procedure as that of the mask blank 30 of Example 1 except that a light-shielding film 2 was formed as follows.

A method of forming the light-shielding film of Example 2 is as follows.

As in Example 1, an etching stopper film 6, a phase shift film 4, and an etching stopper film 5 were formed on a transparent substrate 1.

Then, by performing reactive sputtering (DC sputtering) by a DC power supply using a silicon (Si) target in a mixed gas of krypton (Kr), nitrogen (N₂), and helium (He) (flow rate ratio Kr:N₂:He=2:1:10) as a sputtering gas, a light-shielding film 2 made of silicon and nitrogen was formed on the transparent substrate 1 with a thickness of 55 nm. In addition, power of the DC power supply during sputtering was 1500 W.

Then, as in Example 1, a hard mask film (CrOC film) 3 was formed, and then a resist film 7 was formed with a thickness of 80 nm by a spin coating method to manufacture the mask blank 30 of Example 2.

As in Example 1, an optical density (OD) of the stack of the etching stopper film 6, the phase shift film 4, the light-shielding film 2, the etching stopper film 5, and the hard mask film 3 at a wavelength of 193 nm was measured, and was found to be 3.0 or more. From this result, the mask blank of Example 2 has required light-shielding performance.

As in Example 1, another etching stopper film, phase shift film, etching stopper film, and light-shielding film were formed on a main surface of another transparent substrate under the same film forming conditions as in Example 1. Next, X-ray photoelectron spectroscopy was performed on the light-shielding film on the another transparent substrate. In this X-ray photoelectron spectroscopy, by repeating a step including: irradiating a surface of the light-shielding film with an X-ray (Alkα ray: 1486 eV); measuring an intensity of photoelectrons emitted from the light-shielding film; digging the light-shielding film by Ar gas sputtering at an Ar target voltage of 2.0 kV at a sputtering rate of about 5 nm/min (in terms of SiO₂); irradiating the light-shielding film in a dug region with the X-ray; and measuring an intensity of photoelectrons emitted from the dug region, an Si₂p narrow spectrum at each depth of the light-shielding film was acquired.

FIG. 5 is a diagram illustrating a Si₂p narrow spectrum at a predetermined depth within a range of an internal region in results obtained by performing X-ray photoelectron spectroscopy on the light-shielding film of the mask blank according to Example 2. As illustrated in the drawing, a maximum peak in the Si2p narrow spectrum of Example 2 was 101.1 eV, which satisfied a range of more than 100 eV and 101.5 eV or less.

In addition, the acquired Si₂p narrow spectrum includes each of peaks of a Si—Si bond, a SiₐN_{b} bond, and a Si₃N₄ bond. Then, the peak position of each of the Si—Si bond, the SiₐN_{b} bond, and the Si₃N₄ bond and full widths at half maximum (FWHM) were fixed, and peak separation was performed. Specifically, the peak position of the Si—Si bond was set to 99.65 eV, the peak position of the Si No bond was set to 101.05 eV, the peak position of the Si₃N₄ bond was set to 101.75 eV, and the full width at half maximum FWHM of each of the bonds was set to 1.71, and peak separation was performed.

Then, as in Example 1, a ratio of the number of existing Si—Si bonds, a ratio of the number of existing SiₐN_{b} bonds, and a ratio of the number of existing Si₃N₄ bonds were calculated.

As a result, the ratio of the number of existing Si—Si bonds was 0.269, the ratio of the number of existing SiₐN_{b} bonds was 0.600, and the ratio of the number of existing Si₃N₄ bonds was 0.131. That is, all of the conditions were satisfied that, in the internal region, the ratio of the total existence ratio of the Si₃N₄ bond and the SiₐN_{b} bond to the total existence ratio of the Si₃N₄ bond, the SiₐN_{b} bond, and the Si—Si bond is 0.5 or more, that the ratio of the existence ratio of the SiₐN_{b} bond to the total existence ratio of the Si₃N₄ bond, the SiₐN_{b} bond, and the Si—Si bond is 0.5 or more, and that the ratio of the existence ratio of the Si₃N₄ bond to the total existence ratio of the Si₃N₄ bond, the SiₐN_{b} bond, and the Si—Si bond is 0.03 or more.

In addition, a ratio of the number of existing Si—Si bonds, a ratio of the number of existing Si Np bonds, and a ratio of the number of existing Si₃N₄ bonds were calculated by the same procedure for each Si₂p narrow spectrum at a depth corresponding as that for the internal region of the light-shielding film, other than the depth illustrated in FIG. 5, among the acquired Si₂p narrow spectra at depths of the light-shielding film. As a result, the ratio of the number of existing Si—Si bonds, the ratio of the number of existing SiₐN_{b} bonds, and the ratio of the number of existing Si₃N₄ bonds at any depth of the internal region had the same tendency as that of the ratio of the number of existing Si—Si bonds, the ratio of the number of existing SiₐN_{b} bonds, and the ratio of the number of existing Si₃N₄ bonds at the depth illustrated in FIG. 5. In addition, all of the ratios satisfied the three conditions regarding the ratio of the number of existing bonds described above.

In addition, from the results of the X-ray photoelectron spectroscopy, it was found that an average composition of the internal region of the light-shielding film was Si:N: 0=56.5:43.1:0.4 (atom % ratio).

### [Manufacture of Transfer Mask]

Next, using the mask blank 30 of Example 2, the transfer mask (phase shift mask) 300 of Example 2 was manufactured by the procedure of the third embodiment.

In addition, using another mask blank 30 of Example 2, a first pattern (a hard mask pattern 3a, a light-shielding pattern 2a, an etching stopper pattern 5a, and a phase shift pattern 4a) was formed on the hard mask film 3, the light-shielding film 2, the etching stopper film 5, and the phase shift film 4 (refer to FIG. 3C), and a cross section thereof was observed with a cross-sectional TEM. As a result, a side surface of the light-shielding pattern 2a was located on a side of 2.5 nm with respect to a side surface of the hard mask pattern 3a. That is, a side etching amount of the light-shielding pattern 2a was within an allowable range.

As described above, it can be said that the light-shielding film 2 of the mask blank 30 of Example 2 has desired light-shielding performance, can suppress an increase in film thickness, and can reduce the side etching amount generated by dry etching when a pattern is formed.

In addition, as described in Example 1, it can be said that the light-shielding film 2 has desired light-shielding performance, can suppress an increase in film thickness, and can reduce the side etching amount generated by dry etching during a pattern formation when the light-shielding film 2 of Example 2 is applied to the mask blank 20 having the configuration of the second embodiment or the mask blank 10 having the configuration of the first embodiment.

Next, the phase shift mask 300 of Example 2 was subjected to simulation of a transfer image at the time of exposure transfer to a resist film on a semiconductor device with exposure light of a wavelength of 193 nm using AIMS 193 (manufactured by Carl Zeiss AG). Verification of an exposure transfer image of this simulation indicated that design specifications were sufficiently satisfied. From this result, it can be said that a circuit pattern finally formed on the semiconductor device can be formed with high accuracy even when the phase shift mask 300 of Example 2 is set on a mask stage of an exposure apparatus and exposure transfer is performed to a resist film on the semiconductor device. Therefore, it can be said that the phase shift mask 300 manufactured by the method of manufacturing a transfer mask of Example 2 is a transfer mask with high transfer accuracy.

### Comparative Example 1

### [Manufacture of Mask Blank]

A mask blank 30 of Comparative Example 1 was manufactured by the same procedure as that for the mask blank 30 of Example 1 except that a light-shielding film 2 was formed as follows.

A method of forming the light-shielding film of Comparative Example 1 is as follows.

As in Example 1, an etching stopper film 6, a phase shift film 4, and an etching stopper film 5 were formed on a transparent substrate 1.

Then, by performing reactive sputtering (DC sputtering) by a DC power supply using a silicon (Si) target in a mixed gas of krypton (Kr), nitrogen (N₂), and helium (He) (flow rate ratio Kr:N₂:He=5:1:25) as a sputtering gas, a light-shielding film 2 made of silicon and nitrogen was formed on the transparent substrate 1 with a thickness of 40 nm. In addition, power of the DC power supply during sputtering was 1500 W.

Then, as in Example 1, a hard mask film (CrOC film) 3 was formed, and then a resist film 7 was formed with a thickness of 80 nm by a spin coating method to manufacture the mask blank 30 of Comparative Example 1.

As in Example 1, an optical density (OD) of the stack of the etching stopper film 6, the phase shift film 4, the light-shielding film 2, the etching stopper film 5, and the hard mask film 3 at a wavelength of 193 nm was measured, and was found to be 3.0 or more. From this result, the mask blank of Comparative Example 1 has required light-shielding performance.

As in Example 1, another etching stopper film, phase shift film, etching stopper film, and light-shielding film were formed on a main surface of another transparent substrate under the same film forming conditions as in Example 1, and a heat treatment was further performed under the same conditions. Next, X-ray photoelectron spectroscopy was performed on the light-shielding film on the another transparent substrate after the heat treatment. In this X-ray photoelectron spectroscopy, by repeating a step including: irradiating a surface of the light-shielding film with an X-ray (Alkα ray: 1486 eV); measuring an intensity of photoelectrons emitted from the light-shielding film; digging the light-shielding film by Ar gas sputtering at an Ar target voltage of 2.0 kV at a sputtering rate of about 5 nm/min (in terms of SiO₂); irradiating the light-shielding film in the dug region with the X-ray; and measuring an intensity of photoelectrons emitted from the region, an Si₂p narrow spectrum at each depth of the light-shielding film was acquired.

FIG. 6 is a diagram illustrating a Si₂p narrow spectrum at a predetermined depth within a range of an internal region in results obtained by performing X-ray photoelectron spectroscopy on the light-shielding film of the mask blank according to Comparative Example 1. As illustrated in the drawing, a maximum peak in the Si₂p narrow spectrum of Comparative Example 1 was 99.7 eV, which did not satisfy a range of more than 100 eV and 101.5 eV or less.

In addition, the acquired Si2p narrow spectrum includes each of peaks of a Si—Si bond, a SiₐN_{b} bond, and a Si₃N₄ bond. Then, the peak position of each of the Si—Si bond, the SiₐN_{b} bond, and the Si₃N₄ bond and full widths at half maximum (FWHM) were fixed, and peak separation was performed. Specifically, the peak position of the Si—Si bond was set to 99.7 eV, the peak position of the SiₐN_{b} bond was set to 100.3 eV, the peak position of the Si₃N₄ bond was set to 101.9 eV, and the full width at half maximum FWHM of each of the bonds was set to 1.71, and peak separation was performed.

Then, as in Example 1, a ratio of the number of existing Si—Si bonds, a ratio of the number of existing Si No bonds, and a ratio of the number of existing Si₃N₄ bonds were calculated.

As a result, the ratio of the number of existing Si—Si bonds was 0.716, the ratio of the number of existing SiₐN_{b} bonds was 0.284, and the ratio of the number of existing Si₃N₄ bonds was 0.000. That is, any of the conditions was not satisfied that, in the internal region, the ratio of the total existence ratio of the Si₃N₄ bond and the SiₐN_{b} bond to the total existence ratio of the Si₃N₄ bond, the SiₐN_{b} bond, and the Si—Si bond is 0.5 or more, that the ratio of the existence ratio of the SiₐN_{b} bond to the total existence ratio of the Si₃NA bond, the SiₐN_{b} bond, and the Si—Si bond is 0.5 or more, and that the ratio of the existence ratio of the Si₃N₄ bond to the total existence ratio of the Si₃N₄ bond, the SiₐN_{b} bond, and the Si—Si bond is 0.03 or more.

In addition, a ratio of the number of existing Si—Si bonds, a ratio of the number of existing Si Np bonds, and a ratio of the number of existing Si₃N₄ bonds were calculated by the same procedure for each Si₂p narrow spectrum at a depth corresponding as that for the internal region of the light-shielding film, other than the depth illustrated in FIG. 6, among the acquired Si₂p narrow spectra at depths of the light-shielding film. As a result, the ratio of the number of existing Si—Si bonds, the ratio of the number of existing SiₐN_{b} bonds, and the ratio of the number of existing Si₃N₄ bonds at any depth of the internal region had the same tendency as that of the ratio of the number of existing Si—Si bonds, the ratio of the number of existing SiₐN_{b} bonds, and the ratio of the number of existing Si₃N₄ bonds at the depth illustrated in FIG. 6. In addition, any of the ratios did not satisfy the three conditions regarding the ratio of the number of existing bonds described above.

In addition, from the results of the X-ray photoelectron spectroscopy, it was found that an average composition of the internal region of the light-shielding film was Si:N: 0=77.0:23.0:0.0 (atom % ratio).

### [Manufacture of Transfer Mask]

Next, using the mask blank 30 of Comparative Example 1, the transfer mask (phase shift mask) 300 of Comparative Example 1 was manufactured by the procedure of the third embodiment.

In addition, using another mask blank 30 of Comparative Example 1, a first pattern (a hard mask pattern 3a, a light-shielding pattern 2a, an etching stopper pattern 5a, and a phase shift pattern 4a) was formed on the hard mask film 3, the light-shielding film 2, the etching stopper film 5, and the phase shift film 4 (refer to FIG. 3C), and a cross section thereof was observed with a cross-sectional TEM. As a result, a side surface of the light-shielding pattern 2a was located on a side of 51 nm with respect to a side surface of the hard mask pattern 3a. That is, a side etching amount of the light-shielding pattern 2a was not within an allowable range.

As described above, it can be said that the light-shielding film 2 of the mask blank 30 of Comparative Example 1 is not a film that has desired light-shielding performance, can suppress an increase in film thickness, and can reduce the side etching amount generated by dry etching when a pattern is formed, and thus it is difficult to form a fine pattern.

In addition, also in the method of manufacturing the phase shift mask 200 of the second embodiment, a first pattern (a hard mask pattern 3a, a light-shielding pattern 2a, an etching stopper pattern 5a, and a phase shift pattern 4a) is formed on the hard mask film 3, the light-shielding film 2, the etching stopper film 5, and the phase shift film 4 in the same step as that for the phase shift mask 300 of the third embodiment (refer to FIGS. 2A to 2C). Therefore, it can be said that the light-shielding film 2 is not a film that has desired light-shielding performance, can suppress an increase in film thickness, and can reduce the side etching amount generated by dry etching during a pattern formation when the light-shielding film 2 of Comparative Example 1 is applied to the mask blank 20 having the configuration of the second embodiment.

In addition, the light-shielding film 2 of Comparative Example 1 was formed on another transparent substrate 1 under the same film forming conditions with a film thickness of 45 nm, and the hard mask film 3 was formed thereon. Then, a first pattern (a hard mask pattern 3a and a light-shielding pattern 2a) was formed on the hard mask film 3 and the light-shielding film 2 in a similar step to the binary mask 100 of the first embodiment (refer to FIGS. 1A to 1C), and a cross section thereof was observed with a cross-sectional TEM. As a result, side etching of a side surface of the light-shielding pattern 2a largely proceeded with respect to a side surface of the hard mask pattern 3a, and was not within an allowable range. Therefore, it can be said that the light-shielding film 2 is not a film that has desired light-shielding performance, can suppress an increase in film thickness, and can reduce the side etching amount generated by dry etching during a pattern formation when the light-shielding film 2 of Comparative Example 1 is applied to the mask blank 10 having the configuration of the first embodiment.

Next, the phase shift mask 300 of Comparative Example 1 was subjected to simulation of a transfer image at the time of exposure transfer to a resist film on a semiconductor device with exposure light of a wavelength of 193 nm using AIMS 193 (manufactured by Carl Zeiss AG). Verification of an exposure transfer image of this simulation indicated that design specifications were not satisfied. From this result, it is expected that disconnection or short circuit of a circuit pattern finally formed on the semiconductor device will occur frequently in the circuit pattern when the phase shift mask of Comparative Example 1 is set on a mask stage of an exposure apparatus and exposure transfer is performed onto a resist film on a semiconductor device.

### REFERENCE SIGNS LIST

1 Transparent substrate
2 Light-shielding film
2a Light-shielding pattern
2b Light-shielding pattern
3 Hard mask film
3a Hard mask pattern
3b Hard mask pattern
4 Phase shift film
4a Phase shift pattern
5 Etching stopper film
5a Etching stopper pattern
5a′ Etching stopper pattern
6 Etching stopper film
6a Etching stopper pattern
7 Resist film
7a Resist pattern
8b Resist pattern
10, 20, 30 Mask blank
100 Binary mask
200, 300 Phase shift mask

1. A mask blank comprising:
a transparent substrate; and
a light-shielding film on the transparent substrate, wherein
the light-shielding film comprises silicon and nitrogen,
an internal region of the light-shielding film has a maximum peak at a binding energy in a range in which a Si₂p narrow spectrum obtained by analysis by X-ray photoelectron spectroscopy is more than 100 eV and 101.5 eV or less, and
the internal region of the light-shielding film excludes a back surface side region of the light-shielding film which is closest to the transparent substrate and a front surface side region of the light-shielding film which is opposite to a surface of the transparent substrate.

2. The mask blank according to claim 1, wherein a total content of silicon and nitrogen in the internal region is 95 atom % or more.

3. The mask blank according to claim 1, wherein a nitrogen content in the internal region is 30 atom % or more and less than 50 atom %.

4. The mask blank according to claim 1, wherein the front surface side region extends to a depth of 5 nm from a front surface of the light-shielding film which is opposite to a back surface of the light-shielding film which is closest to the transparent substrate.

5. The mask blank according to claim 1,
wherein the back surface side region extends to a depth of 5 nm from a back surface of the light-shielding film which is closest to the transparent substrate.

6. The mask blank according to claim 1, wherein the binding energy is more than 100 eV and 101.5 eV or less as measured by an AlKα ray.

7. The mask blank according to claim 1, wherein a ratio of a total existence ratio of a Si₃N₄ bond and a SiₐN_{b} bond (in which b/[a+b]<4/7) to a total existence ratio of the Si₃N₄ bond, the SiₐN_{b} bond, and a Si—Si bond in the internal region is 0.5 or more.

8. The mask blank according to claim 7, wherein a ratio of an existence ratio of the SiₐN_{b} bond to the total existence ratio of the Si₃N₄ bond, the SiₐN_{b} bond, and the Si—Si bond in the internal region is 0.5 or more.

9. The mask blank according to claim 7, wherein a ratio of an existence ratio of the Si₃N₄ bond to the total existence ratio of the Si₃N₄ bond, the SiₐN_{b} bond, and the Si—Si bond in the internal region is 0.03 or more.

10. The mask blank according to claim 1, wherein a phase shift film is disposed between the transparent substrate and the light-shielding film, the phase shift film being made of a material which is etchable by dry etching using a gas including fluorine.

11. A phase shift mask comprising:
a transparent substrate;
a phase shift film having a transfer pattern on the transparent substrate; and
a light-shielding film having a pattern including a light-shielding band on the phase shift film, wherein
the phase shift film is made of a material which is etchable by dry etching using a gas including fluorine,
the light-shielding film comprises silicon and nitrogen,
an internal region of the light-shielding film has a maximum peak at a binding energy in a range in which a Si₂p narrow spectrum obtained by analysis by X-ray photoelectron spectroscopy is more than 100 eV and 101.5 eV or less, and
the internal region of the light-shielding film excludes a back surface side region of the light-shielding film which is closest to the transparent substrate and a front surface side region of the light-shielding film which is opposite to a surface of the transparent substrate.

12. The phase shift mask according to claim 11, wherein a total content of silicon and nitrogen in the internal region is 95 atom % or more.

13. The phase shift mask according to claim 11, wherein a nitrogen content in the internal region is 30 atom % or more and less than 50 atom %.

14. The phase shift mask according to claim 11, wherein the front surface side region extends to a depth of 5 nm from a front surface of the light-shielding film which is opposite to a back surface of the light-shielding film which is closest to the transparent substrate.

15. The phase shift mask according to claim 11, wherein the back surface side region extends to a depth of 5 nm from a back surface of the light-shielding film which is closest to the transparent substrate.

16. The phase shift mask according to claim 11, wherein the binding energy is more than 100 eV and 101.5 eV or less as measured by an AlKα ray.

17. The phase shift mask according to claim 11, wherein a ratio of a total existence ratio of a Si₃N₄ bond and a SiₐN_{b} bond (in which b/[a+b]<4/7) to a total existence ratio of the Si₃N₄ bond, the SiₐN_{b} bond, and a Si—Si bond in the internal region is 0.5 or more.

18. The phase shift mask according to claim 17, wherein a ratio of an existence ratio of the SiₐN_{b} bond to the total existence ratio of the Si₃N₄ bond, the SiₐN_{b} bond, and the Si—Si bond in the internal region is 0.5 or more.

19. The phase shift mask according to claim 17, wherein a ratio of an existence ratio of the Si₃N₄ bond to the total existence ratio of the Si₃N₄ bond, the SiₐN_{b} bond, and the Si—Si bond in the internal region is 0.03 or more.

20. A method of manufacturing a semiconductor device, the method comprising performing exposure transfer of the transfer pattern to a resist film on a semiconductor substrate using the phase shift mask according to claim 11.
